(19) United States
(12) Patent Application Publication
(10) Pub. No.: US 2021/0165148 A1
(43) Pub. Date: Jun. 3, 2021

(54) LAMINATE AND IMAGE DISPLAY DEVICE

(71) Applicant: FUJIFILM Corporation, Tokyo (JP)

(72) Inventors: Yuzo FUJIKI, Kanagawa (JP); Fumitake MITOBE, Kanagawa (JP); Jun TAKEDA, Kanagawa (JP)

(73) Assignee: FUJIFILM Corporation, Tokyo (JP)

(21) Appl. No.: 17/172,619

(22) Filed: Feb. 10, 2021

Related U.S. Application Data
(63) Continuation of application No. PCT/JP2019/031412, filed on Aug. 8, 2019.

(30) Foreign Application Priority Data
Aug. 15, 2018 (JP) 2018-152948

(51) Int. Cl. G02B 5/30; B32B 7/023; B32B 27/36

(52) U.S. Cl. CPC G02B 5/3016; B32B 7/023; B32B 27/36; B32B 2255/26; B32B 2307/412; B32B 2307/42; B32B 2255/10; B32B 2457/202

(57) ABSTRACT

An object of the present invention is to provide a laminate having excellent display performance and moisture and heat durability in a case of being used in an image display device, and an image display device including the laminate. The laminate of the present invention is a laminate including a light absorption anisotropic film, and a liquid crystal layer which is adjacent to the light absorption anisotropic film, in which the light absorption anisotropic film is a film formed of a composition containing a dichroic material, the liquid crystal layer is a layer which contains a liquid crystal compound aligned therein and has a thickness of 300 nm or less, and an absorption axis of the light absorption anisotropic film and a slow axis of the liquid crystal layer are parallel to each other.

### CROSS-REFERENCE TO RELATED APPLICATIONS

This application is a Continuation of PCT International Application No. PCT/JP2019/031412 filed on Aug. 8, 2019, which claims priority under 35 U.S.C. § 119(a) to Japanese Patent Application No. 2018-152948 filed on Aug. 15, 2018. Each of the above applications is hereby expressly incorporated by reference, in its entirety, into the present application.

### BACKGROUND OF THE INVENTION

### 1. Field of the Invention

The present invention relates to a laminate and an image display device.

### 2. Description of the Related Art

In the related art, in a case where an attenuation function, a polarization function, a scattering function, or a light shielding function of irradiation light including laser light or natural light is required, a device that is operated according to principles different for each function is used. Therefore, products corresponding to the above-described functions are also produced by production processes different for each function.

For example, a linear polarizer or a circular polarizer is used in an image display device (for example, a liquid crystal display device) to control optical rotation or birefringence in display. Further, a circular polarizer is also used even in an organic light emitting diode (OLED) to prevent reflection of external light.

In the related art, iodine has been widely used as a dichroic material in these polarizers, but a polarizer that uses an organic coloring agent in place of iodine as a dichroic material has also been examined.

For example, WO2017/154695A discloses a coloring composition that contains a predetermined dichroic dye compound and a liquid crystal compound.

### SUMMARY OF THE INVENTION

As a result of examination on a laminate that includes a light absorption anisotropic film formed of the coloring composition described in WO2017/54695A, the present inventors have clarified that the reflectivity increases depending on the material of a layer (for example, an alignment film) adjacent to the light absorption anisotropic film, and thus the display performance may be degraded in a case where the laminate is used in an image display device. Similarly, the present inventors have clarified that the moisture and heat durability may be degraded even in a case where a material that decreases the reflectivity is selected as the layer (for example, an alignment film) adjacent to the light absorption anisotropic film.

Therefore, an object of the present invention to provide a laminate having excellent display performance and moisture and heat durability in a case of being used in an image display device, and an image display device including the laminate.

As a result of intensive examination conducted by the present inventors in order to achieve the above-described object, it was found that a laminate which includes, as a layer adjacent to a light absorption anisotropic film formed of a composition containing a dichroic material, a liquid crystal layer having a predetermined thickness and a predetermined positional relationship with an absorption axis of the light absorption anisotropic film has excellent display performance and moisture and heat durability in a case of being used in an image display device, thereby completing the present invention.

That is, the present inventors found that the above-described object can be achieved by employing the following configurations.

[1] A laminate comprising: a light absorption anisotropic film; and a liquid crystal layer which is adjacent to the light absorption anisotropic film, in which the light absorption anisotropic film is a film formed of a composition containing a dichroic material, the liquid crystal layer is a layer which contains a liquid crystal compound aligned therein and has a thickness of 300 nm or less, and an absorption axis of the light absorption anisotropic film and a slow axis of the liquid crystal layer are parallel to each other.

[2] The laminate according to [1], in which an average refractive index n₅₅₀ of the liquid crystal layer at a wavelength of 550 nm is 1.50 to 1.75.

[3] The laminate according to [1] or [2], in which an in-plane refractive index anisotropy Δn of the liquid crystal layer at a wavelength of 550 nm is 0.03 or greater.

[4] The laminate according to any one of [1] to [3], further comprising: a transparent support; and an alignment film, in which the transparent support, the alignment film, the light absorption anisotropic film, and the liquid crystal layer are provided in order.

[5] The laminate according to any one of [1] to [3], further comprising: a transparent support; and an alignment film, in which the transparent support, the alignment film, the liquid crystal layer, and the light absorption anisotropic film are provided in order.

[6] The laminate according to any one of [1] to [3], further comprising: a transparent support; an alignment film; and a second liquid crystal layer, in which the transparent support, the alignment film, the liquid crystal layer, the light absorption anisotropic film, and the second liquid crystal layer are provided in order, the second liquid crystal layer is a layer which contains a liquid crystal compound aligned therein and has a thickness of 300 nm or less, and the absorption axis of the light absorption anisotropic film and a slow axis of the second liquid crystal layer are parallel to each other.

[7] The laminate according to any one of [1] to [6], in which the light absorption anisotropic film is a film formed of a composition containing the dichroic material and a liquid crystal compound.

[8] The laminate according to any one of [1] to [7], in which the dichroic material is a compound represented by Formula (1).

[9] The laminate according to any one of [1] to [8], in which the dichroic material is a compound represented by Formula (2).

[10] The laminate according to [9], in which in Formula (2), A⁴ represents a phenylene group.

[11] The laminate according to [9] or [10], in which in Formula (2), at least one of L³ or L⁴ contains a crosslinkable group.

[12] The laminate according to any one of [9] to [11], in which in Formula (2), both L³ and L⁴ contain a crosslinkable group.

[13] The laminate according to [11] or [12], in which the crosslinkable group is an acryloyl group or a methacryloyl group.

[14] The laminate according to any one of [1] to [13], further comprising: a λ/4 plate.

[15] An image display device comprising: the laminate according to any one of [1] to [14].

According to the present invention, it is possible to provide a laminate having excellent display performance and moisture and heat durability in a case of being used in an image display device, and an image display device including the laminate.

### BRIEF DESCRIPTION OF THE DRAWINGS

FIG. 1A is a schematic cross-sectional view showing an example of a laminate of the present invention.

FIG. 1B is a schematic cross-sectional view showing an example of the laminate of the present invention.

FIG. 1C is a schematic cross-sectional view showing an example of the laminate of the present invention.

FIG. 1D is a schematic cross-sectional view showing an example of a known laminate.

### DESCRIPTION OF THE PREFERRED EMBODIMENTS

Hereinafter, the present invention will be described in detail.

The description of constituent elements described below may be made based on typical embodiments of the present invention, but the present invention is not limited to such embodiments.

In addition, in the present specification, a numerical range shown using “to” indicates a range including numerical values described before and after “to” as a lower limit and an upper limit.

Further, in the present specification, the terms parallel, orthogonal, horizontal, and vertical do not indicate parallel, orthogonal, horizontal, and vertical in a strict sense, but indicate a range of parallel ±10°, a range of orthogonal ±10°, a range of horizontal ±10°, and a range of vertical ±10 respectively.

In the present specification, materials corresponding to respective components may be used alone or in combination of two or more kinds thereof as the respective components. Here, in a case where two or more kinds of materials corresponding to respective components are used in combination, the content of the components indicates the total content of the combined materials unless otherwise specified.

Further, in the present specification, “(meth)acrylate” is a notation representing “acrylate” or “methacrylate”, “(meth)acryl” is a notation representing “acryl” or “methacryl”, and “(meth)acryloyl” is a notation representing “acryloyl” or “methacryloyl”.

[Laminate]

A laminate according to the embodiment of the present invention includes a light absorption anisotropic film, and a liquid crystal layer which is adjacent to the light absorption anisotropic film.

In the laminate according to the embodiment of the present invention, the light absorption anisotropic film is a film formed of a composition containing a dichroic material, and the liquid crystal layer is a layer which contains a liquid crystal compound aligned therein and has a thickness of 300 nm or less.

Further, in the laminate of the present invention, the light absorption anisotropic film and the liquid crystal layer are provided such that an absorption axis of the light absorption anisotropic film and a slow axis of the liquid crystal layer are parallel to each other, that is, the angle between the absorption axis of the light absorption anisotropic film and the slow axis of the liquid crystal layer is −10° to +10°. Further, the angle between the absorption axis of the light absorption anisotropic film and the slow axis of the liquid crystal layer is preferably −5° to +5°, more preferably −3° to +3°, still more preferably −1° to +1, and particularly preferably 0°.

Here, the “slow axis” of the liquid crystal layer indicates a direction in which the in-plane refractive index of the liquid crystal layer is maximum, and the “absorption axis” of the light absorption anisotropic film indicates a direction in which the absorbance is the highest.

In the present invention, as described above, in a case where a laminate which includes, as a layer adjacent to a light absorption anisotropic film formed of a composition containing a dichroic material, a liquid crystal layer having a predetermined thickness and a predetermined positional relationship with an absorption axis of the light absorption anisotropic film is used in an image display device, the display performance and the moisture and heat durability are improved.

The reason for this is not clear, but the present inventors assume as follows.

First, as a result of examination on the reason why the display performance and the moisture and heat durability are degraded in a case where a known laminate (for example, a polarizing element) of the related art which includes a light absorption anisotropic film formed of a composition containing a dichroic material is used in an image display device, it is considered that an increase in refractive index anisotropy of the dichroic material in a visible light region (a wavelength of approximately 400 to 700 nm) leads to an increase in internal reflection at the interface between the light absorption anisotropic film and an alignment film adjacent to the light absorption anisotropic film, and thus the antireflection function of the polarizing element is degraded.

Therefore, in the present invention, it is considered that since the internal reflection at the interface between the light absorption anisotropic film and the liquid crystal layer can be controlled in a case where a liquid crystal layer containing a liquid crystal compound aligned therein and having a thickness of 300 nm or less is used as the layer adjacent to the light absorption anisotropic film formed of a composition containing a dichroic material, the antireflection function in moisture and heat aging is unlikely to be degraded even in a case where the material having degraded moisture and heat durability is used as the alignment film. It is considered that since the directions in which the refractive index of the light absorption anisotropic film and the refractive index of the liquid crystal layer are high are parallel to each other in a case where the absorption axis of the light absorption anisotropic film and the slow axis of the liquid crystal layer are parallel to each other, the internal reflection at the interface between the light absorption anisotropic film and the liquid crystal layer can be suppressed.

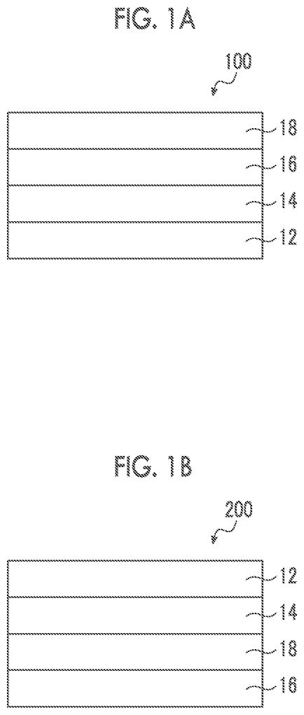

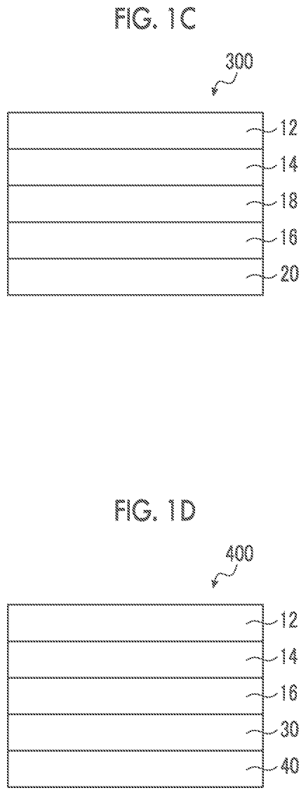

FIGS. 1A to 1C are schematic cross-sectional views respectively showing an example of the laminate according to the embodiment of the present invention.

Here, a laminate 100 shown in FIG. 1A is a laminate having a layer configuration (hereinafter, also referred to as a “configuration A”) in which a liquid crystal layer 18, a light absorption anisotropic film 16, an alignment film 14, and a transparent support 12 are provided in order.

Further, a laminate 200 shown in FIG. 1B is a laminate having a layer configuration (hereinafter, also referred to as a “configuration B”) in which the transparent support 12, the alignment film 14, the liquid crystal layer 18, and the light absorption anisotropic film 16 are provided in order.

Further, a laminate 300 shown in FIG. 1C is a laminate having a layer configuration (hereinafter, also referred to as a “configuration C”) in which the transparent support 12, the alignment film 14, the liquid crystal layer 18, the light absorption anisotropic film 16, and a second liquid crystal layer 19 are provided in order.

In the above-described configurations A to C, other layers may be provided in a space between layers other than the space between the light absorption anisotropic film and the liquid crystal layer which are provided in adjacent to each other and may be provided on the surface of the outermost layer. For example, in the configuration A, a barrier layer may be provided on a surface of the liquid crystal layer 18 opposite to a side where the light absorption anisotropic film 16 is provided, and a λ/4 plate may be provided on a surface of the transparent support 12 opposite to a side where the alignment film 14 is provided. Similarly, in the configuration B, a barrier layer and a λ/4 plate may be provided in order on a surface of the light absorption anisotropic film 16 opposite to a side where the liquid crystal layer 18 is provided.

Meanwhile, FIG. 1D is a schematic cross-sectional view showing a known laminate, and a laminate 400 shown in FIG. 1D is a laminate having a layer configuration (hereinafter, also referred to as a “configuration D”) in which the transparent support 12, the alignment film 14, the light absorption anisotropic film 16, a barrier layer 30, and an optically anisotropic layer 40 are provided in order.

Hereinafter, the light absorption anisotropic film, the liquid crystal layer, an optional transparent support, an optional alignment film, and the like which are included in the laminate according to the embodiment of the present invention will be described in detail.

[Light Absorption Anisotropic Film]

The light absorption anisotropic film included in the laminate according to the embodiment of the present invention is a film formed of a composition (hereinafter, also referred to as a “composition for forming a light absorption anisotropic film”) containing a dichroic material.

In the present invention, the degree of alignment of the light absorption anisotropic film is preferably 0.92 or greater and more preferably 0.94 or greater.

Here, in a case where the degree of alignment increases, the refractive index anisotropy of the light absorption anisotropic film tends to increase, and the reflection at the interface between the light absorption anisotropic film and the adjacent layer tends to increase. Therefore, the effects of the present invention are significant in a case where the degree of alignment of the light absorption anisotropic film is 0.92 or greater.

Further, the degree of alignment of the light absorption anisotropic film is a value calculated by setting the light absorption anisotropic film on a sample table and measuring the absorbance of the light absorption anisotropic film using a multichannel spectrometer (product name “QE65000”, manufactured by Ocean Optics, Inc.) in a state in which a linear polarizer is inserted into a light source side of an optical microscope (product name “ECLIPSE E600 POL”, manufactured by Nikon Corporation).

Degree of alignment: S=[(Az0/Ay0)−1]/[(Az0/Ay0)+2]

Az0: Absorbance of light absorption anisotropic film with respect to polarized light in absorption axis direction

Ay0: Absorbance of light absorption anisotropic film with respect to polarized light in transmission axis direction

Further, in the present invention, the light absorption anisotropic film may exhibit reverse wavelength dispersibility.

Here, the expression “the light absorption anisotropic film exhibits reverse wavelength dispersibility” indicates that in a case where the in-plane retardation (Re) value at a specific wavelength (visible light region) is measured, the Re value is identical or increases as the measurement wavelength increases.

Here, the refractive index of the light absorption anisotropic film is a value measured using a spcctroscop ellipsometer M-2000U (manufactured by J. A. Woollam Co., Inc.).

Specifically, a direction in which the in-plane refractive index of the light absorption anisotropic film is maximum is defined as an x-axis, a direction orthogonal thereto is defined as a y-axis, a normal direction with respect to the in-plane is defined as a z-axis, the refractive index in an x-axis direction is defined as Nxt, the refractive index in a y-axis direction is defied as Nyt, and the refractive index in a z-axis direction is defined as Nzt, at a predetermined wavelength t [nm]. For example, in a case where the measurement wavelength is 550 nm, the refractive index in the x-axis direction is set as Nx₅₅₀, the refractive index in the y-axis direction is set as Ny₅₅₀, and the refractive index in the z-axis direction is set as Nz₅₅₀.

In the present invention, from the viewpoint of further controlling the internal reflectivity at the interface between the light absorption anisotropic film and the liquid crystal layer, the average refractive index N₅₅₀ of the light absorption anisotropic film at a wavelength of 550 nm is preferably 1.50 to 1.75 and more preferably 1.55 to 1.70.

Here, the average refractive index N₅₅₀ thereof at a wavelength of 550 nm is a value calculated according to Equation (R20).

Average refractive index N₅₅₀=(Nx₅₅₀+Ny₅₅₀)/2 (R20)

The thickness of the light absorption anisotropic film is not particularly limited, but is preferably 100 to 8000 nm and more preferably 300 to 5000 nm from the viewpoint of the flexibility in a case where the laminate according to the embodiment of the present invention is used in a polarizing element.

<Dichroic Material>

The dichroic material contained in the composition for forming a light absorption anisotropic film is not particularly limited, and examples thereof include a visible light absorbing material (dichroic dye), a luminescent material (such as a fluorescent material or a phosphorescent material), an ultraviolet absorbing material, an infrared absorbing material, a nonlinear optical material, a carbon nanotube, and an inorganic material (for example, a quantum rod). Further, known dichroic materials (dichroic dyes) of the related art can be used.

From the viewpoint of improving the degree of alignment of the light absorption anisotropic film to be formed, specific suitable examples thereof include those described in paragraphs [0067] to [0071] of JP2013-228706A, paragraphs [0008] to [0026] of JP2013-227532A, paragraphs [0008] to [0015] of JP2013-209367A, paragraphs [0045] to [0058] of JP2013-014883A, paragraphs [0012] to [0029] of JP2013-109090A, paragraphs [0009] to [0017] of JP2013-101328A, paragraphs [0051] to [0065] of JP2013-037353A, paragraphs [0049] to [0073] of JP2012-063387A, paragraphs [0016] to [0018] of JP1999-305036A (JP-H11-305036A), paragraphs [0009] to [0011] of JP2001-133630A, paragraphs [0030] to [0169] of JP2011-215337A, paragraphs [0021] to [0075] of JP2010-106242A, paragraphs [0011] to [0025] of JP2010-215846A, paragraphs [0017] to [0069] of JP2011-048311A, paragraphs [0013] to [0133] of JP2011-213610A, paragraphs [0074] to [0246] of JP2011-237513A, paragraphs [0005] to [0051] of JP2016-006502A, paragraphs [0005] to [0041] of WO2016/060173A, paragraphs [0008] to [0062] of WO 2016/136561A, paragraphs [0014] to [0033] of WO2017/154835A, paragraphs [0014] to [0033] of WO2017/154695A, and paragraphs [0013] to [0037] of WO2017/195833A.

In the present invention, from the viewpoint of further improving the degree of alignment of the light absorption anisotropic film to be formed, it is preferable that the dichroic material contained in the composition for forming a light absorption anisotropic film is a compound represented by Formula (1) (hereinafter, also referred to as a “specific dichroic material”).

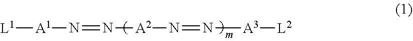

Here, in Formula (1), A¹, A², and A³ each independently represent a divalent aromatic group which may have a substituent.

Further, in Formula (1), L¹ and L² each independently represent a substituent.

Further, in Formula (1), m represents an integer of 1 to 4, and in a case where m represents an integer of 2 to 4, a plurality of A²'s may be the same as or different from each other. Further, it is preferable that m represents 1 or 2.

The “divalent aromatic group which may have a substituent” represented by A¹, A², and A³ in Formula (1) will be described.

Examples of the substituent include a substituent group G described in paragraphs [0237] to [0240] of JP2011-237513A. Among these, a halogen atom, an alkyl group, an alkoxy group, an alkoxycarbonyl group (such as methoxycarbonyl or ethoxycarbonyl), and an aryloxycarbonyl group (such as phenoxycarbonyl, 4-methylphenoxycarbonyl, or 4-methoxyphenylcarbonyl) are suitable, an alkyl group is more suitable, and an alkyl group having 1 to 5 carbon atoms is still more suitable.

In addition, examples of the divalent aromatic group include a divalent aromatic hydrocarbon group and a divalent aromatic heterocyclic group.

Examples of the divalent aromatic hydrocarbon group include an arylene group having 6 to 12 carbon atoms, and specific examples thereof include a phenylene group, a cumenylene group, a mesitylene group, a tolylene group, and a xylylene group. Among these, a phenylene group is preferable.

Further, as the divalent aromatic heterocyclic group, a group derived from a monocyclic or bicyclic heterocycle is preferable. Examples of the atoms other than the carbon atom constituting the aromatic heterocyclic group include a nitrogen atom, a sulfur atom, and an oxygen atom. In a case where the aromatic heterocyclic group has a plurality of atoms constituting a ring other than the carbon atom, these atoms may be the same as or different from each other. Specific examples of the aromatic heterocyclic group include a pyridylene group (pyridine-diyl group), a quinolylene group (quinoline-diyl group), an isoquinolylene group (isoquinoline-diyl group), a benzothiadiazole-diyl group, a phthalimido-diyl group, and a thienothiazole-diyl group (hereinafter, also referred to as a “thienothiazolegroup”).

Among the above-described divalent aromatic groups, a divalent aromatic hydrocarbon group is preferable.

Here, it is preferable that any one of A¹, A², or A³ represents a divalent thienothiazole group which may have a substituent. Further, specific examples of the substituent of the divalent thienothiazole group are the same as the substituents of the “divalent aromatic group which may have a substituent” described above, and the preferred embodiments are also the same as described above.

Further, it is more preferable that A² among A¹, A², and A³ represents a divalent thienothiazole group. In this case, A¹ and A² represent a divalent aromatic group which may have a substituent.

In a case where A² represents a divalent thienothiazole group, it is preferable that at least one of A¹ or A² represents a divalent aromatic hydrocarbon group which may have a substituent and more preferable that both A¹ and A² represent a divalent aromatic hydrocarbon group which may have a substituent.

The “substituent” represented by L¹ and L² in Formula (1) will be described. As the substituent, a group to be introduced to increase the solubility or the nematic liquid crystallinity, a group having an electron-donating property or an electron-withdrawing property which is to be introduced to adjust the color tone of a coloring agent, or a group containing a crosslinkable group (polymerizable group) to be introduced to fix the alignment is preferable.

Examples of the substituent include an alkyl group (preferably an alkyl group having 1 to 20 carbon atoms, more preferably an alkyl group having 1 to 12 carbon atoms, and particularly preferably an alkyl group having 1 to 8 carbon atoms, and examples thereof include a methyl group, an ethyl group, an isopropyl group, a tert-butyl group, an n-octyl group, an n-decyl group, an n-hexadecyl group, a cyclopropyl group, a cyclopentyl group, and a cyclohexyl group), an alkenyl group (preferably an alkenyl group having 2 to 20 carbon atoms, more preferably an alkenyl group having 2 to 12 carbon atoms, and particularly preferably an alkenyl group having 2 to 8 carbon atoms, and examples thereof include a vinyl group, an aryl group, a 2-butenyl group, and a 3-pentenyl group), an alkynyl group (preferably an alkynyl group having 2 to 20 carbon atoms, more preferably an alkynyl group 2 to 12 carbon atoms, and particularly preferably an alkynyl group having 2 to 8 carbon atoms, and examples thereof include a propargyl group and a 3-pentynyl group), an aryl group (preferably an aryl group having 6 to 30 carbon atoms, more preferably an aryl group having 6 to 20 carbon atoms, and particularly preferably an aryl group having 6 to 12 carbon atoms, and examples thereof include a phenyl group, a 2,6-diethylphenyl group, a 3,5-ditrifluoromethylphenyl group, a styryl group, a naphthyl group, and a biphenyl group), a substituted or unsubstituted amino group (preferably an amino group having 0 to 20 carbon atoms, more preferably an amino group having 0 to 10 carbon atoms, and particularly preferably an amino group having 0 to 6 carbon atoms, and examples thereof include an unsubstituted amino group, a methylamino group, a dimethylamino group, a diethylamino group, and an anilino group), an alkoxy group (preferably an alkoxy group having 1 to 20 carbon atoms and more preferably an alkoxy group having 1 to 15 carbon atoms, and examples thereof include a methoxy group, an ethoxy group, and a butoxy group), an oxycarbonyl group (preferably an oxycarbonyl group having 2 to 20 carbon atoms, more preferably an oxycarbonyl group having 2 to 15 carbon atoms, and particularly preferably an oxycarbonyl group having 2 to 10 carbon atoms, and examples thereof include a methoxycarbonyl group, an ethoxycarbonyl group, and a phenoxycarbonyl group), an acyloxy group (preferably an acyloxy group having 2 to 20 carbon atoms, more preferably an acyloxy group having 2 to 10 carbon atoms, and particularly preferably an acyloxy group having 2 to 6 carbon atoms, and examples thereof include an acetoxy group, a benzoyloxy group, an acryloyl group, and a methacryloyl group), an acylamino group (preferably an acylamino group having 2 to 20 carbon atoms, more preferably an acylamino group having 2 to 10 carbon atoms, and particularly preferably an acylamino group having 2 to 6 carbon atoms, and examples thereof include an acetylamino group and a benzoylamino group), an alkoxycarbonylamino group (preferably an alkoxycarbonylamino group having 2 to 20 carbon atoms, more preferably an alkoxycarbonylamino group having 2 to 10 carbon atoms, and particularly preferably an alkoxycarbonylamino group having 2 to 6 carbon atoms, and examples thereof include a methoxycarbonylamino group), an aryloxycarbonylamino group (preferably an aryloxycarbonylamino group having 7 to 20 carbon atoms, more preferably an aryloxycarbonylamino group having 7 to 16 carbon atoms, and particularly preferably an aryloxycarbonylamino group having 7 to 12 carbon atoms, and examples thereof include a phenyloxycarbonylamino group), a sulfonylamino group (preferably a sulfonylamino group having 1 to 20 carbon atoms, more preferably a sulfonylamino group having 1 to 10 carbon atoms, and particularly preferably a sulfonylamino group having 1 to 6 carbon atoms, and examples thereof include a methanesulfonylamino group and a benzenesulfonylamino group), a sulfamoyl group (preferably a sulfamoyl group having 0 to 20 carbon atoms, more preferably a sulfamoyl group having 0 to 10 carbon atoms, and particularly preferably a sulfamoyl group having 0 to 6 carbon atoms, and examples thereof include a sulfamoyl group, a methylsulfamoyl group, a dimethylsulfamoyl group, and a phenylsulfamoyl group), a carbamoyl group (preferably a carbamoyl group having 1 to 20 carbon atoms, more preferably a carbamoyl group having 1 to 10 carbon atoms, and particularly preferably a carbamoyl group having 1 to 6 carbon atoms, and examples thereof include an unsubstituted carbamoyl group, a methylcarbamoyl group, a diethylcarbamoyl group, and a phenylcarbamoyl group), an alkylthio group (preferably an alkylthio group having 1 to 20 carbon atoms, more preferably an alkylthio group having 1 to 10 carbon atoms, and particularly preferably an alkylthio group having 1 to 6 carbon atoms, and examples thereof include a methylthio group and an ethylthio group), an arylthio group (preferably an arylthio group having 6 to 20 carbon atoms, more preferably an arylthio group having 6 to 16 carbon atoms, and particularly preferably an arylthio group having 6 to 12 carbon atoms, and examples thereof include a phenylthio group), a sulfonyl group (preferably a sulfonyl group having 1 to 20 carbon atoms, more preferably a sulfonyl group having 1 to 10 carbon atoms, and particularly preferably a sulfonyl group having 1 to 6 carbon atoms, and examples thereof include a mesyl group and a tosyl group), a sulfinyl group (preferably a sulfinyl group having 1 to 20 carbon atoms, more preferably a sulfinyl group having 1 to 10 carbon atoms, and particularly preferably a sulfinyl group having 1 to 6 carbon atoms, and examples thereof include a methanesulfinyl group and a benzenesulfinyl group), a ureido group (preferably a ureido group having (to 20 carbon atoms, more preferably a ureido group having 1 to 10 carbon atoms, and particularly preferably a ureido group having 1 to 6 carbon atoms, and examples thereof include an unsubstituted ureido group, a methylureido group, and a phenylureido group), a phosphoric acid amide group (preferably a phosphoric acid amide group having 1 to 20 carbon atoms, more preferably a phosphoric acid amide group having 1 to 10 carbon atoms, and particularly preferably a phosphoric acid amide group having 1 to 6 carbon atoms, and examples thereof include a diethylphosphoric acid amide group and a phenylphosphoric acid amide group), a hydroxyl group, a mercapto group, a halogen atom (such as a fluorine atom, a chlorine atom, a bromine atom, or an iodine atom), a cyano group, a nitro group, a hydroxamic acid group, a sulfino group, a hydrazino group, an imino group, an azo group, a heterocyclic group (preferably a heterocyclic group having 1 to 30 carbon atoms and more preferably a heterocyclic group having 1 to 12 carbon atoms, and examples thereof include a heterocyclic group having a heteroatom such as a nitrogen atom, an oxygen atom, or a sulfur atom, and examples of the heterocyclic group having a heteroatom include an epoxy group, an oxetanyl group, an imidazolyl group, a pyridyl group, a quinolyl group, a furyl group, a piperidyl group, a morpholino group, a benzoxazolyl group, a benzimidazolyl group, and a benzthiazolyl group), and a silyl group (preferably a silyl group having 3 to 40 carbon atoms, more preferably a silyl group having 3 to 30 carbon atoms, and particularly preferably a silyl group having 3 to 24 carbon atoms, and examples thereof include a trimethylsilyl group and a triphenylsilyl group).

These substituents may be further substituted with these substituents. Further, in a case where two or more substituents are present, these may be the same as or different from each other. Further, these may be bonded to each other to form a ring where possible.

Among these, as the substituent represented by L¹ and L², an alkyl group which may have a substituent, an alkenyl group which may have a substituent, an alkynyl group which may have a substituent, an aryl group which may have a substituent, an alkoxy group which may have a substituent, an oxycarbonyl group which may have a substituent, an acyloxy group which may have a substituent, an acylamino group which may have a substituent, an amino group which may have a substituent, an alkoxycarbonylamino group which may have a substituent, a sulfonylamino group which may have a substituent, a sulfamoyl group which may have a substituent, a carbamoyl group which may have a substituent, an alkylthio group which may have a substituent, a sulfonyl group which may have a substituent, a ureido group which may have a substituent, a nitro group, a hydroxy group, a cyano group, an imino group, an azo group, a halogen atom, and a heterocyclic group are preferable, and an alkyl group which may have a substituent, an alkenyl group which may have a substituent, an aryl group which may have a substituent, an alkoxy group which may have a substituent, an oxycarbonyl group which may have a substituent, an acyloxy group which may have a substituent, an amino group which may have a substituent, a nitro group, an imino group, and an azo group are more preferable.

It is preferable that at least one of L¹ or L² contains a crosslinkable group (polymerizable group) and more preferable that both L¹ and L² contain a crosslinkable group.

Specific examples of the crosslinkable group include the polymerizable groups described in paragraphs [0040] to [0050] of JP2010-244038A. Among these, from the viewpoint of improving the reactivity and the synthetic suitability, an acryloyl group, a methacryloyl group, an epoxy group, an oxetanyl group, and a styryl group are preferable, and an acryloyl group and a methacryloyl group are more preferable.

Suitable embodiments of L¹ and L² include an alkyl group substituted with the above-described crosslinkable group, a dialkylamino group substituted with the above-described crosslinkable group, and an alkoxy group substituted with the above-described crosslinkable group.

In the present invention, from the viewpoint of further improving the degree of alignment of the light absorption anisotropic film to be formed, it is preferable that the specific dichroic material is a compound represented by Formula (2).

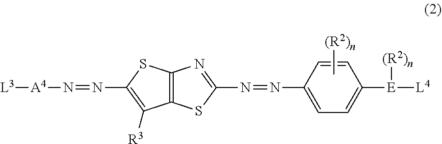

Here, in Formula (2), A⁴ represents a divalent aromatic group which may have a substituent.

Further, in Formula (2), L³ and L⁴ each independently represent a substituent.

Further, in Formula (2), E represents any of a nitrogen atom, an oxygen atom, or a sulfur atom.

Further, in Formula (2), R¹ represents any group or atom of a hydrogen atom, a halogen atom, an alkyl group which may have a substituent, or an alkoxy group which may have a substituent.

Further, in Formula (2), R² represents a hydrogen atom or an alkyl group which may have a substituent.

Further, in Formula (2), R³ represents a hydrogen atom or a substituent.

Further, in Formula (2), n represents 0 or 1. Here, n is 1 in a case where E represents a nitrogen atom, and n is 0 in a case where E represents an oxygen atom or a sulfur atom.

Specific examples and suitable embodiments of the “divalent aromatic group which may have a substituent” represented by A⁴ in Formula (2) are the same as those for the “divalent aromatic group which may have a substituent” represented by A¹ to A³ in Formula (1) described above.

As a particularly preferred embodiment of A⁴, A⁴ represents a phenylene group.

Specific examples and suitable embodiments of the “substituent” represented by L and L⁴ in Formula (2) are the same as those for the “substituent” represented by L and L in Formula (1).

As a more suitable embodiment of L³ and L⁴, at least one of L³ or L⁴ contains a crosslinkable group. As a still more suitable embodiment thereof, both L³ and L⁴ contain a crosslinkable group. In this manner, the degree of alignment of the specific dichroic material contained in the light absorption anisotropic film is further improved, and the high temperature durability and the moisture and heat durability of the laminate are further improved.

Further, as a more suitable embodiment of the crosslinkable group of L³ and L, an acryloyl group or a methacryloyl group is exemplified.

In Formula (2), E represents any of a nitrogen atom, an oxygen atom, or a sulfur atom. Among these, from the viewpoint of the synthetic suitability, a nitrogen atom is preferable.

Further, from the viewpoint that it is easy to make the specific dichroic material have absorption on a short wavelength side (for example, a dichroic material that has a maximum absorption wavelength in a range of approximately 500 to 530 nm), it is preferable that E in Formula (1) represents an oxygen atom.

In addition, from the viewpoint that it is easy to make the specific dichroic material have absorption on a long wavelength side (for example, a dichroic material that has a maximum absorption wavelength at approximately 600 nm), it is preferable that E in Formula (1) represents a nitrogen atom.

In Formula (2), R¹ represents any group or atom of a hydrogen atom, a halogen atom, an alkyl group which may have a substituent, or an alkoxy group which may have a substituent. Among these, a hydrogen atom or an alkyl group which may have a substituent is preferable.

Next, the “alkyl group which may have a substituent” and the “alkoxy group which may have a substituent” represented by R¹ will be described.

Examples of the substituent include a halogen atom.

Examples of the alkyl group include a linear, branched, or cyclic alkyl group having 1 to 8 carbon atoms. Among these, a linear alkyl group having 1 to 6 carbon atoms is preferable, a linear alkyl group having 1 to 3 carbon atoms is more preferable, and a methyl group or an ethyl group is still more preferable.

Examples of the alkoxy group include an alkoxy group having 1 to 8 carbon atoms. Among the examples, an alkoxy group having 1 to 6 carbon atoms is preferable, an alkoxy group having 1 to 3 carbon atoms is more preferable, and a methoxy group or an ethoxy group is still more preferable.

In Formula (2), R² represents a hydrogen atom or an alkyl group which may have a substituent and preferably an alkyl group which may have a substituent.

Specific examples and suitable embodiments of the “alkyl group which may have a substituent” as R² are the same as those for the “alkyl group which may have a substituent” as R¹ in Formula (2). Therefore, the description thereof will not be provided.

Further, R² represents a group that is present in Formula (2) in a case where E represents a nitrogen atom (that is, a case where n represents 1). Further, R² represents a group that is not present in Formula (2) in a case where E represents an oxygen atom or a sulfur atom (that is, a case where n represents 0).

In Formula (2), R³ represents a hydrogen atom or a substituent.

Specific examples and suitable embodiments of the “substituent” represented by R³ are the same as those for the substituents in the “divalent aromatic group which may have a substituent”, and preferred embodiments are also the same as described above. Therefore, the description thereof will not be provided.

In Formula (2), n represents 0 or 1. Here, n is 1 in a case where E represents a nitrogen atom, and n is 0 in a case where E represents an oxygen atom or a sulfur atom.

Specific examples of the specific dichroic material represented by Formula (1) include the compounds described in paragraphs [0051] to [0081] of JP2010-152351 A, and the content of which is incorporated in the present specification by reference.

Among these, specific examples of the compound represented by Formula (2) include the compounds shown below.

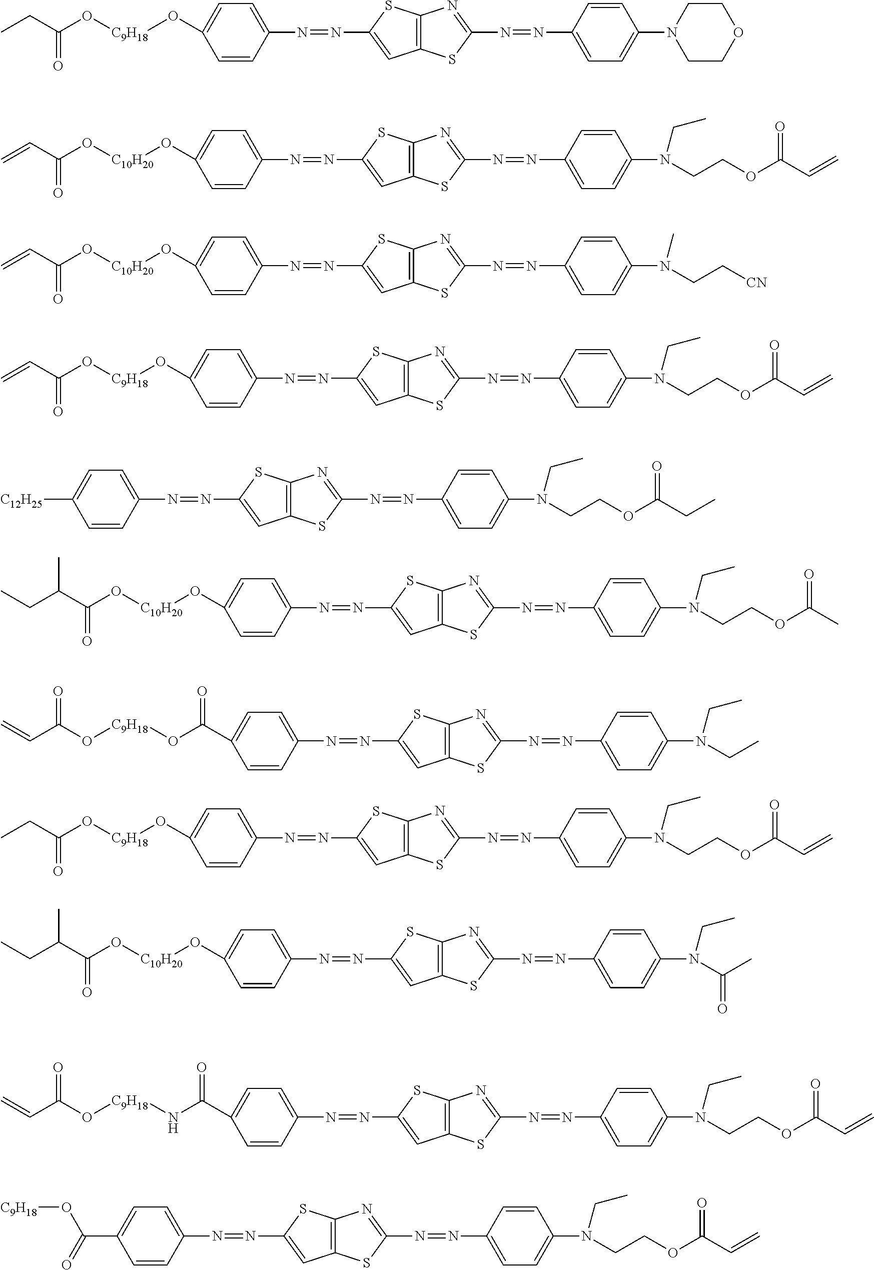

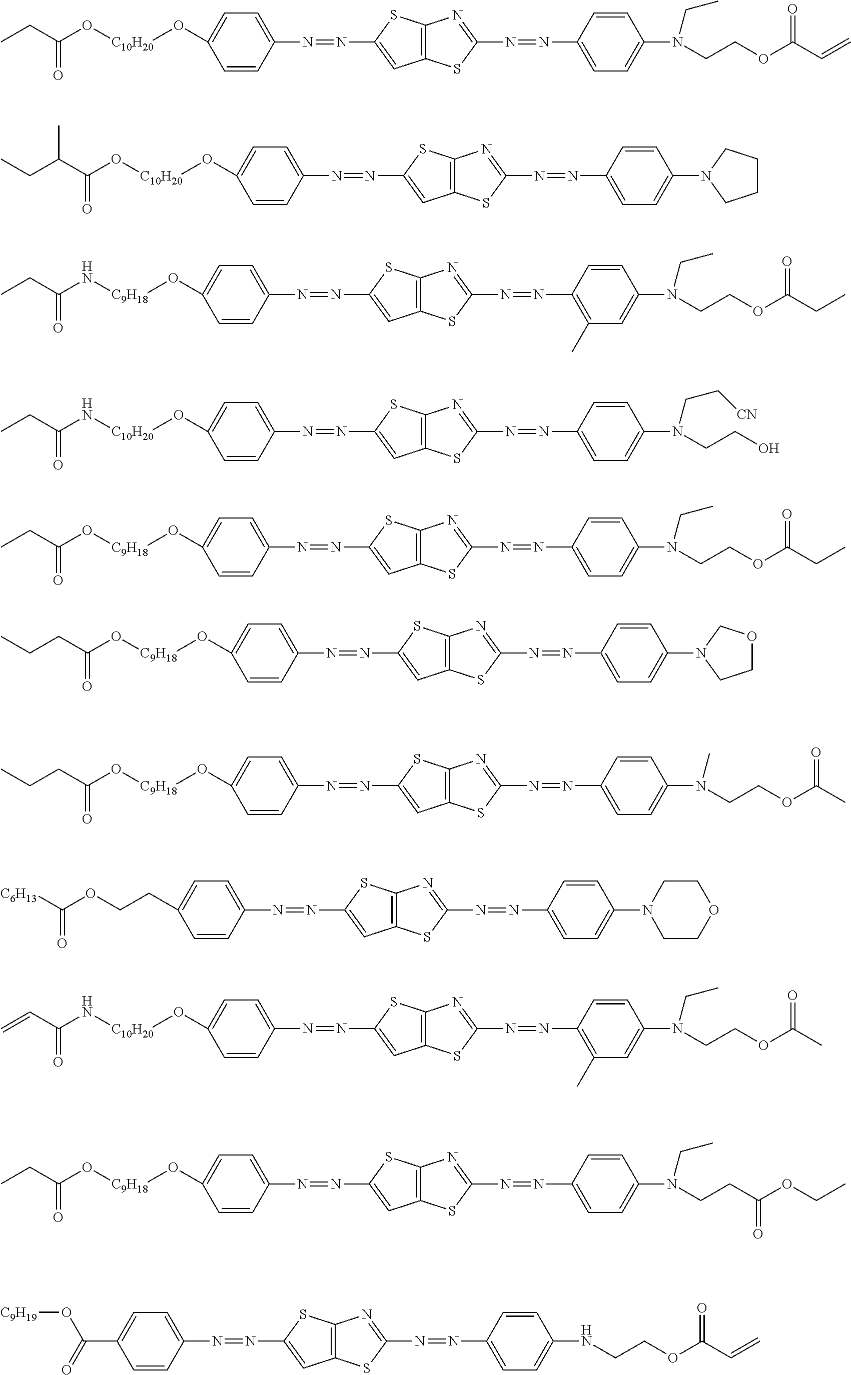

The content of the dichroic material is preferably 8% to 22% by mass and more preferably 10 to 20% by mass with respect to the total mass of the solid content of the light absorption anisotropic film. In a case where the content of the dichroic material is in the above-described range, a light absorption anisotropic film having a high degree of alignment can be obtained even in a case where the light absorption anisotropic film is formed into a thin film. Therefore, a light absorption anisotropic film having excellent flexibility is likely to be obtained.

Further, the dichroic material may be used alone or in combination of two or more kinds thereof. In a case where the composition contains two or more dichroic materials, it is preferable that the total amount of the dichroic materials is in the above-described range.

<Liquid Crystal Compound>

In the present invention, from the viewpoint of the dichroic material can be aligned with a high degree of alignment while the precipitation of the dichroic material is restrained, it is preferable that the composition for forming a light absorption anisotropic film contains a liquid crystal compound together with the dichroic material described above.

As such a liquid crystal compound, both a low-molecular-weight liquid crystal compound and a polymer liquid crystal compound can be used.

Here, the “low-molecular-weight liquid crystal compound” indicates a liquid crystal compound having no repeating units in the chemical structure.

Further, the “polymer liquid crystal compound” indicates a liquid crystal compound having repeating units in the chemical structure.

Examples of the low-molecular-weight liquid crystal compound include those described in JP2013-228706A.

Examples of the polymer liquid crystal compound include thermotropic liquid crystal polymers described in JP2011-237513A. Further, the polymer liquid crystal compound may contain a crosslinkable group (such as an acryloyl group or a methacryloyl group) at a terminal.

In a case where the composition for forming a light absorption anisotropic film contains a liquid crystal compound, the content of the liquid crystal compound is preferably 70 to 95 parts by mass and more preferably 70 to 90 parts by mass with respect to 100 parts by mass which is the total amount of the dichroic material and the liquid crystal compound in the composition for forming a light absorption anisotropic film.

The liquid crystal compound may be used alone or in combination of two or more kinds thereof. In a case where the composition contains two or more kinds of liquid crystal compounds, it is preferable that the total amount of the liquid crystal compounds is in the above-described range.

<Polymerization Initiator>

The composition for forming a light absorption anisotropic film may contain a polymerization initiator.

The polymerization initiator is not particularly limited, but a compound having photosensitivity, that is, a photopolymerization initiator is preferable.

As the photopolymerization initiator, various compounds can be used without any particular limitation. Examples of the photopolymerization initiator include α-carbonyl compounds (U.S. Pat. Nos. 2,367,661A and 2,367,670A), acyloin ether (U.S. Pat. No. 2,448,828A), α-hydrocarbon-substituted aromatic acyloin compounds (U.S. Pat. No. 2,722,512A), polynuclear quinone compounds (U.S. Pat. Nos. 3,046,127A and 2,951,758A), a combination of a triarylimidazole dimer and a p-aminophenyl ketone (U.S. Pat. No. 3,549,367A), acridine and phenazine compounds (JP1985-105667A (JP-S60-105667A) and U.S. Pat. No. 4,239,850A), oxadiazole compounds (U.S. Pat. No. 4,212,970A), and acylphosphine oxide compounds (JP1988-040799B (JP-S63-040799B), JP1993-029234B (JP-H05-029234B), JP1998-095788A (JP-H10-095788A), and JP1998-029997A (JP-H10-029997A)).

Commercially available products can also be used as such a photopolymerization initiator, and examples thereof include IRGACURE (hereinafter, also abbreviated as “Irg”)-184, IRGACURE-907, IRGACURE-369, IRGACURE-651, IRGACURE-819, IRGACURE OXE-01, IRGACURE-OXE-02 (all manufactured by BASF SE).

In a case where the composition for forming a light absorption anisotropic film contains a polymerization initiator, the content of the polymerization initiator is preferably 0.01 to 30 parts by mass and more preferably 0.1 to 15 parts by mass with respect to 100 parts by mass which is the total amount of the dichroic material and the liquid crystal compound in the composition for forming a light absorption anisotropic film. The durability of the light absorption anisotropic film is excellent in a case where the content of the polymerization initiator is 0.01 parts by mass or greater, and the degree of alignment of the light absorption anisotropic film is further enhanced in a case where the content thereof is 30 parts by mass or less.

The polymerization initiator may be used alone or in combination of two or more kinds thereof. In a case where the composition contains two or more kinds of polymerization initiators, it is preferable that the total amount of the polymerization initiators is in the above-described range.

<Interface Modifier>

It is preferable that the composition for forming a light absorption anisotropic film contains an interface modifier.

In a case where the composition contains an interface modifier, the smoothness of the coated surface is improved, the degree of alignment is further improved, and cissing and unevenness are suppressed so that the in-plane uniformity is expected to be improved.

As the interface modifier, those that allow dichroic materials and liquid crystal compounds to be horizontally aligned on a side of a coated surface are preferable, and compounds (horizontal alignment agents) described in paragraphs [0253] to [0293] of JP2011-237513A can be used.

In a case where the composition for forming a light absorption anisotropic film contains an interface modifier, the content of the interface modifier is preferably 0.001 to 5 parts by mass and more preferably 0.01 to 3 parts by mass with respect to 100 parts by mass which is the total amount of the dichroic material and the liquid crystal compound in the composition for forming a light absorption anisotropic film.

The interface modifier may be used alone or in combination of two or more kinds thereof. In a case where the composition contains two or more kinds of interface modifiers, it is preferable that the total amount of the interface modifiers is in the above-dcscribed range.

<Solvent>

From the viewpoint of workability or the like, it is preferable that the composition for forming a light absorption anisotropic film contains a solvent.

Examples of the solvent include organic solvents such as ketones (such as acetone, 2-butanone, methyl isobutyl ketone, cyclopentanone, and cyclohexanone), ethers (such as dioxane and tetrahydrofuran), aliphatic hydrocarbons (such as hexane), alicyclic hydrocarbons (such as cyclohexane), aromatic hydrocarbons (such as benzene, toluene, xylene, and trimethylbenzene), halogenated carbons (such as dichloromethane, trichloromethane, dichloroethane, dichlorobenzene, and chlorotoluene), esters (such as methyl acetate, ethyl acetate, and butyl acetate), alcohols (such as ethanol, isopropanol, butanol, and cyclohexanol), cellosolves (such as methyl cellosolve, ethyl cellosolve, and 1,2-dimethoxyethane), cellosolve acetates, sulfoxides (such as dimethyl sulfoxide), amides (such as dimethylformamide and dimethylacetamide), and heterocyclic compounds (such as pyridine); and water. These solvents may be used alone or in combination of two or more kinds thereof.

Among these solvents, it is preferable to use organic solvents and more preferable to use halogenated carbons or ketones.

In a case where the composition for forming a light absorption anisotropic film contains a solvent, the content of the solvent is preferably 80% to 99% by mass, more preferably 83% to 97% by mass, and particularly preferably 85% to 95% by mass with respect to the total mass of the composition for forming a light absorption anisotropic film.

These solvents may be used alone or in combination of two or more kinds thereof. In a case where the composition contains two or more kinds of solvents, it is preferable that the total amount of the solvents is in the above-described range.

<Forming Method>

The method of forming the light absorption anisotropic film formed of the composition for forming a light absorption anisotropic film described above is not particularly limited, and a method of including a step of coating an alignment film or liquid crystal layer described below with the composition for forming a light absorption anisotropic film described above according to the layer configuration to form a coating film (hereinafter, also referred to as a “coating film forming step”) and a step of aligning a liquid crystal component contained in the coating film (hereinafter, also referred to as an “aligning step”) in order is exemplified.

Further, the liquid crystal component is a component that contains not only the above-described liquid crystal compound but also the dichroic material having a liquid crystallinity in a case where the dichroic material has a liquid crystallinity.

(Coating Film Forming Step)

The coating film forming step is a step of coating an alignment film or a liquid crystal layer with the composition for forming a light absorption anisotropic film to form a coating film.

The alignment film or the liquid crystal layer can be easily coated with the composition for forming a light absorption anisotropic film by using the composition for forming a light absorption anisotropic film which contains the above-described solvent or using a liquid such as a melt obtained by heating the composition for forming a light absorption anisotropic film.

Specific examples of the method of coating the film with the composition for forming a light absorption anisotropic film include known methods such as a roll coating method, a gravure printing method, a spin coating method, a wire bar coating method, an extrusion coating method, a direct gravure coating method, a reverse gravure coating method, a die coating method, a spraying method, and an ink jet method.

(Aligning Step)

The aligning step is a step of aligning the liquid crystal component contained in the coating film. In this manner, a light absorption anisotropic film is obtained.

The aligning step may include a drying treatment. Components such as a solvent can be removed from the coating film by performing the drying treatment. The drying treatment may be performed according to a method of allowing the coating film to stand at room temperature for a predetermined time (for example, natural drying) or a method of heating the coating film and/or blowing air to the coating film.

Here, the liquid crystal component contained in the composition for forming a light absorption anisotropic film may be aligned by the coating film forming step or the drying treatment described above. For example, in an embodiment in which the composition for forming a light absorption anisotropic film is prepared as a coating solution containing a solvent, a coating film having light absorption anisotropy (that is, a light absorption anisotropic film) is obtained by drying the coating film and removing the solvent from the coating film.

In a case where the drying treatment is performed at a temperature higher than or equal to the transition temperature of the liquid crystal component contained in the coating film to the liquid crystal phase, the heat treatment described below may not be performed.

The transition temperature of the liquid crystal component contained in the coating film to the liquid crystal phase is preferably 10° C. to 250° C. and more preferably 25° C. to 190° C. from the viewpoint of the manufacturing suitability or the like. It is preferable that the transition temperature is 10° C. or higher from the viewpoint that a cooling treatment or the like for lowering the temperature to a temperature range in which a liquid crystal phase is exhibited is not necessary. Further, it is preferable that the transition temperature is 250° C. or lower from the viewpoint that a high temperature is not required even in a case of setting an isotropic liquid state at a temperature higher than the temperature range in which a liquid crystal phase is temporarily exhibited, and waste of thermal energy and deformation and deterioration of a substrate can be reduced.

It is preferable that the aligning step includes a heat treatment. In this manner, since the liquid crystal component contained in the coating film can be aligned, the coating film after being subjected to the heat treatment can be suitably used as the light absorption anisotropic film.

From the viewpoints of the manufacturing suitability and the like, the heat treatment is performed at a temperature of preferably 10° C. to 250° C. and more preferably 25° C. to 190° C. Further, the heating time is preferably 1 to 300 seconds and more preferably 1 to 60 seconds.

The aligning step may include a cooling treatment to be performed after the heat treatment. The cooling treatment is a treatment of cooling the heated coating film to room temperature (20° C. to 25° C.). In this manner, the alignment of the liquid crystal component contained in the coating film can be fixed. The cooling means is not particularly limited, and the cooling can be performed using a known method.

The light absorption anisotropic film can be obtained by performing the above-described steps.

In the present embodiment, a drying treatment, a heat treatment, and the like are exemplified as the method of aligning the liquid crystal component contained in the coating film, but the method is not limited thereto, and the liquid crystal component can be aligned by a known alignment treatment.

(Other Steps)

The method of producing the light absorption anisotropic film may include a step of curing the light absorption anisotropic film after the aligning step (hereinafter, also referred to as a “curing step”).

The curing step is performed by heating the light absorption anisotropic film and/or irradiating the film with light (exposing the film to light), for example, in a case where the light absorption anisotropic film contains a crosslinkable group (polymerizable group). Between these, it is preferable that the curing step is performed by irradiating the film with light.

Various light sources such as infrared rays, visible light, and ultraviolet rays can be used as the light source for curing, but ultraviolet rays are preferable. In addition, ultraviolet rays may be applied while the film is heated during curing, or ultraviolet rays may be applied through a filter that transmits rays with only a specific wavelength.

In a case where the exposure is performed while the film is heated, the heating temperature during the exposure depends on the transition temperature of the liquid crystal component contained in the light absorption anisotropic film to a liquid crystal phase, but is preferably 25° to 140° C.

Further, the exposure may be performed in a nitrogen atmosphere. In a case where the curing of the light absorption anisotropic film proceeds by radical polymerization, since the inhibition of polymerization by oxygen is reduced, it is preferable that exposure is performed in a nitrogen atmosphere.

[Liquid Crystal Layer]

The liquid crystal layer included the laminate according to the embodiment of the present invention is not particularly limited as long as the liquid crystal layer contains a liquid crystal compound aligned therein and has a thickness of 300 nm or less, but a layer formed of a composition that contains a liquid crystal compound but does not contain a dichroic material (hereinafter, also referred to as a “composition for forming a liquid crystal layer”) is preferable.

Here, the refractive index of the liquid crystal layer is a value measured using a spectroscopic ellipsometer M-2000U (manufactured by Woollam Co.) similarly to the light absorption anisotropic film.

Specifically, a direction in which the in-plane refractive index of the liquid crystal layer is maximum is defined as an x-axis, a direction orthogonal thereto is defined as a y-axis, a normal direction with respect to the in-plane is defined as a z-axis, the refractive index in an x-axis direction is defined as nxt, the refractive index in a y-axis direction is defied as nyt, and the refractive index in a z-axis direction is defined as nzt, at a predetermined wavelength t [nm]. For example, in a case where the measurement wavelength is 550 nm, the refractive index in the x-axis direction is referred to as nx₅₅₀, the refractive index in the y-axis direction is referred to as ny₅₅₀, and the refractive index in the z-axis direction is referred to as nz₅₅₀.

In the present invention, from the viewpoint of further controlling the internal reflectivity at the interface between the light absorption anisotropic film and the liquid crystal layer, the average refractive index nₐᵥₑ of the liquid crystal layer at a wavelength of 400 to 700 nm is preferably 1.50 to 1.75 and more preferably 1.55 to 1.70.

Here, the average refractive index nₐᵥₑ thereof at a wavelength of 400 to 700 nm is a value obtained by measuring nxt and nyt for each 1 nm in a wavelength range of 400 to 700 nm and performing calculation based on Equation (R1) using an average value nxₐᵥₑ of the refractive indices in the x-axis direction and an average value nyₐᵥₑ of the refractive indices in the y-axis direction.

Average refractive index nₐᵥₑ=(nxₐᵥₑ+nyₐᵥₑ)/2 (R1)

nxₐᵥₑ=(nx₄₀₀+nx₄₀₁+nx₄₀₂+ . . . +nx₆₉₉+nx₇₀₀)/301

nyₐᵥₑ=(ny₄₀₀+ny₄₀₁+ny₄₀₂+ . . . +ny₆₉₉+ny₇₀₀)/301

In the present invention, from the viewpoint of further controlling the internal reflectivity at the interface between the light absorption anisotropic film and the liquid crystal layer, the average refractive index n₅₅₀ of the liquid crystal layer at a wavelength of 550 nm is preferably 1.50 to 1.75 and more preferably 1.55 to 1.70.

Here, the average refractive index n₅₅₀ at a wavelength of 550 nm is a value calculated by Equation (R2).

Average refractive index n₅₅₀=(nx₅₅₀+ny₅₅₀)/2 (R2)

In the present invention, from the viewpoint of further controlling the internal reflectivity at the interface between the light absorption anisotropic film and the liquid crystal layer, the in-plane refractive index anisotropy Δn of the liquid crystal layer at a wavelength of 550 nm is preferably 0.03 or greater, more preferably 0.05 or greater, and still more preferably 0.10 or greater.

Refractive index anisotropy Δn=nx₅₅₀−ny₅₅₀ (R3)

The thickness of the liquid crystal layer is not particularly limited as long as the thickness thereof is 300 nm or less, but is preferably 10 to 300 nm, more preferably 10 to 200 nm, still more preferably 10 to 100 nm, and particularly preferably 15 nm or greater and less than 80 nm.

<Liquid Crystal Compound>

The liquid crystal compound contained in the composition for forming a liquid crystal layer is not particularly limited.

Typically, the liquid crystal compound can be classified into a rod type compound and a disk type compound depending on the shape thereof. In addition, the above-described types of compounds respectively include a low-molecular-weight type compound and a polymer type compound. The polymer indicates a compound having a degree of polymerization of 100 or greater (Polymer Physics and Phase Transition Dynamics, written by Masao Doi, p. 2, Iwanami Shoten, Publishers, 1992).

In the present invention, any liquid crystal compound can be used, but it is preferable to use a rod-like liquid crystal compound (hereinafter, also abbreviated as “CLC”) or a discotic liquid crystal compound (hereinafter, also abbreviated as “DLC”) is used and more preferable to use a rod-like liquid crystal compound. Further, two or more kinds of rod-like liquid crystal compounds, two or more kinds of disk-like liquid crystal compounds, or a mixture of a rod-like liquid crystal compound and a disk-like liquid crystal compound may be used.

In the present invention, from the viewpoint of fixing the above-described liquid crystal compound, it is preferable to use a liquid crystal compound having a polymerizable group and more preferable that the liquid crystal compound contains two or more polymerizable groups in one molecule. Further, in a case where a mixture of two or more kinds of liquid crystal compounds is used, it is preferable that at least one liquid crystal compound contains two or more polymerizable groups in one molecule. Further, the liquid crystal compound is not required to exhibit liquid crystallinity after the compound is fixed by polymerization.

Further, the kind of the polymerizable group is not particularly limited, but a functional group capable of carrying out the addition polymerization reaction is preferable, and a polymerizable ethylenically unsaturated group or a ring polymerizable group is preferable. More specifically, preferred examples thereof include a (meth)acryloyl group, a vinyl group, a styryl group, and an allyl group. Among these, a (meth)acryloyl group is more preferable. Further, the (meth)acryloyl group is a notation that indicates a methacryloyl group or an acryloyl group.

For example, those described in claim 1 of JP1999-513019A (JP-H11-513019A) and paragraphs [0026] to [0098] of JP2005-289980A can be preferably used as the rod-like liquid crystal compound, and those described in paragraphs [0020] to [0067] of JP2007-108732A and paragraphs [0013] to [0108] of JP2010-244038A can be preferably used as the discotic liquid crystal compound, but the present invention is not limited thereto.

<Other Components>

Specific examples of components other than the liquid crystal compound contained in the composition for forming a liquid crystal layer include the polymerization initiator, the surfactant, and the solvent described in the composition containing the dichroic material (the composition for forming a light absorption anisotropic film).

<Forming Method>

The method of forming the liquid crystal layer formed of the composition for forming a liquid crystal layer described above is not particularly limited, and a method of including a step of coating the following alignment film or the above-described light absorption anisotropic film with the composition for forming a liquid crystal layer described above according to the layer configuration to form a coating film (hereinafter, also referred to as a “coating film forming step”) and a step of aligning a liquid crystal component contained in the coating film (hereinafter, also referred to as an “aligning step”) in order is exemplified.

Here, examples of the coating film forming step and the aligning step include the same steps as described above in the method of forming the light absorption anisotropic film.

[Transparent Support]

The laminate according to the embodiment of the present invention may include a transparent support.

Here, the “transparent” in the present invention indicates that the transmittance of visible light is 60% or greater, preferably 80% or greater, and particularly preferably 90% or greater.

Specific examples of the transparent support include a glass substrate and a plastic substrate. Among these, a plastic substrate is preferable.

Examples of the plastic constituting the plastic substrate include a polyolefin such as polyethylene, polypropylene, or a norbornene-based polymer; a cyclic olefin-based resin; polyvinyl alcohol; polyethylene terephthalate; polymethacrylic acid ester; polyacrylic acid ester; cellulose ester such as triacetyl cellulose (TAC), diacetyl cellulose, or cellulose acetate propionate; polyethylene naphthalate; polycarbonate; polysulfone; polyether sulfone; polyether ketone; polyphenylene sulfide; polyphenylene oxide, and polyimide. Among these, from the viewpoints availability from the market and excellent transparency, cellulose ester, a cyclic olefin-based resin, polyethylene terephthalate, polymethacrylic acid ester, or polyimide is particularly preferable.

It is preferable that the thickness of the transparent support is set to be small to the extent that the strength and the workability can be maintained from the viewpoint that the mass thereof enables the support to be practically handled and sufficient transparency can be ensured.

The thickness of the glass substrate is preferably 100 to 3000 μm and more preferably 100 to 1000 μm.

The thickness of the plastic substrate is preferably 5 to 300 μm and more preferably 5 to 200 μm.

Further, in a case where the laminate according to the embodiment of the present invention is used as a circularly polarizing plate (particularly in a case where the laminate is used as a circularly polarizing plate for mobile devices), the thickness of the transparent support is preferably 5 to 100 μm.

[Alignment Film]

The laminate according to the embodiment of the present invention may include an alignment film between the transparent support described above and the light absorption anisotropic film or liquid crystal layer described above.

An alignment film can be formed by a method such as a rubbing treatment performed on a film surface of an organic compound (preferably a polymer), oblique deposition of an inorganic compound, formation of a layer having microgrooves, or accumulation of an organic compound (such as w-tricosanoic acid, dioctadecylmethylammonium chloride, or methyl stearate) according to a Langmuir-Blodgett method (LB film). Further, an alignment film in which an alignment function is generated by application of an electric field, application of a magnetic field, or irradiation with light is also known.

Among these, in the present invention, an alignment film formed by performing a rubbing treatment is preferable from the viewpoint of easily controlling the pretilt angle of the alignment film, and a photo-alignment film formed by irradiation with light is also preferable from the viewpoint of the uniformity of alignment.

<Rubbing Treatment Alignment Film>

A polymer material used for the alignment film formed by performing a rubbing treatment is described in a plurality of documents, and a plurality of commercially available products can be used. In the present invention, polyvinyl alcohol or polyimide and derivatives thereof are preferably used. The alignment film can refer to the description on page 43, line 24 to page 49, line 8 of WO2001/088574A1. The thickness of the alignment film is preferably 0.01 to 10 μm and more preferably 0.01 to 2 μm.

<Photo-Alignment Film>

A photo-alignment compound used for an alignment film formed by irradiation with light is described in a plurality of documents. In the present invention, preferred examples thereof include azo compounds described in JP2006-285197A, JP2007-076839A, JP2007-138138A, JP2007-094071A, JP2007-121721A, JP2007-140465A, JP2007-156439A, JP2007-133184A, JP2009-109831A, JP38838486, and JP4151746B, aromatic ester compounds described in JP2002-229039A, maleimide and/or alkenyl-substituted nadiimide compounds having a photo-alignment unit described in JP2002-265541A and JP2002-317013A, photocrosslinkable silane derivatives described in JP4205195B and JP4205198B, photocrosslinkable polyimides, polyamides, or esters described in JP2003-520878A, JP2004-529220A, and JP4162850B. Among these, azo compounds, photocrosslinkable polyimides, polyamides, or esters are more preferable.

Among these, a photosensitive compound containing a photoreactive group that is generated by at least one of dimerization or isomerization due to the action of light is preferably used as the photo-alignment compound.

Further, it is preferable that the photoreactive group has a skeleton of at least one derivative or compound selected from the group consisting of a cinnamic acid derivative, a coumarin derivative, a chalcone derivative, a maleimide derivative, an azobenzene compound, a polyimide compound, a stilbene compound, and a spiropyran compounds.

The photo-alignment film formed of the above-described material is irradiated with linearly polarized light or non-polarized light to produce a photo-alignment film.

In the present specification, the “irradiation with linearly polarized light” and the “irradiation with non-polarized light” are operations for causing a photoreaction in the photo-alignment material. The wavelength of the light to be used varies depending on the photo-alignment material to be used and is not particularly limited as long as the wavelength is required for the photoreaction. The peak wavelength of light to be used for irradiation with light is preferably 200 nm to 700 nm, and ultraviolet light having a peak wavelength of 400 nm or less is more preferable.

Examples of the light source used for irradiation with light include commonly used light sources, for example, lamps such as a tungsten lamp, a halogen lamp, a xenon lamp, a xenon flash lamp, a mercury lamp, a mercury xenon lamp, and a carbon arc lamp, various lasers [such as a semiconductor laser, a helium neon laser, an argon ion laser, a helium cadmium laser, and a yttrium aluminum garnet (YAG) laser], a light emitting diode, and a cathode ray tube.

As a method of obtaining linearly polarized light, a method of using a polarizing plate (for example, an iodine polarizing plate, a dichroic dye polarizing plate, or a wire grid polarizing plate), a method of using a prism-based element (for example, a Glan-Thompson prism) or a reflective polarizer for which a Brewster's angle is used, or a method of using light emitted from a laser light source having polarized light can be employed. In addition, only light having a required wavelength may be selectively applied using a filter or a wavelength conversion element.

In a case where light to be applied is linearly polarized light, a method of applying light vertically or obliquely to the upper surface of the alignment film or the surface of the aligmnent film from the rear surface is employed. The incidence angle of light varies depending on the photo-alignment material, but is preferably 0° to 90° (vertical) and more preferably 40° to 90°.

In a case where light to be applied is non-polarized light, the alignment film is irradiated with non-polarized light obliquely. The incidence angle is preferably 10° to 80°, more preferably 20° to 60°, and still more preferably 30° to 50°.

The irradiation time is preferably 1 minute to 60 minutes and more preferably 1 minute to 10 minutes.

In a case where patterning is required, a method of performing irradiation with light using a photomask as many times as necessary for pattern preparation or a method of writing a pattern by laser light scanning can be employed.

[Barrier Layer]

As described above, the laminate according to the embodiment of the present invention may include a barrier layer on the surface of the liquid crystal layer 18 opposite to the side where the light absorption anisotropic film 16 is provided in the configuration A shown in FIG. 1A and may include a barrier layer on the surface of the light absorption anisotropic film 16 opposite to the side where the liquid crystal layer 18 is provided in the configuration B shown in FIG. 1B.

Here, the barrier layer is also referred to as a gas barrier layer (oxygen barrier layer) and has a function of protecting the polarizing element of the present invention from gas such as oxygen in the atmosphere, the moisture, or the compound contained in an adjacent layer.

The barrier layer can refer to, for example, the description in paragraphs [0014] to [0054] of JP2014-159124A, paragraphs [0042] to [0075] of JP2017-121721A, paragraphs [0045] to [0054] of JP2017-115076A, paragraphs [0010] to [0061] of JP2012-213938A, and paragraphs [0021] to [0031] of JP2005-169994A.

[λ/4 Plate]

The laminate according to the embodiment of the present invention may include a λ/4 plate.

Here, the “λ/4 plate” is a plate having a λ/4 function, specifically, a plate having a function of converting linearly polarized light having a specific wavelength into circularly polarized light (or converting circularly polarized light into linearly polarized light).

Specific examples of the λ/4 plate include those described in US2015/0277006A.

Specific examples of a λ/4 plate having a single-layer structure include a stretched polymer film and a phase difference film in which an optically anisotropic layer having a λ/4 function is provided on a support. Further, specific examples of a λ/4 plate having a multilayer structure include a broadband λ/4 plate obtained by laminating a λ/4 plate and a λ/2 plate.

[Pressure Sensitive Adhesive Layer]

The laminate according to the embodiment of the present invention may include a pressure sensitive adhesive layer on a surface to which the λ/4 plate is bonded, from the viewpoint of bonding the λ/4 plate described above.

Examples of the pressure sensitive adhesive contained in the pressure sensitive adhesive layer include a rubber-based pressure sensitive adhesive, an acrylic pressure sensitive adhesive, a silicone-based pressure sensitive adhesive, a urethane-based pressure sensitive adhesive, a vinyl alkyl ether-based pressure sensitive adhesive, a polyvinyl alcohol-based pressure sensitive adhesive, a polyvinylpyrrolidone-based pressure sensitive adhesive, a polyacrylamide-based pressure sensitive adhesive, and a cellulose-based pressure sensitive adhesive.

Among these, an acrylic pressure sensitive adhesive (pressure sensitive adhesive) is preferable from the viewpoints of the transparency, the weather resistance, the heat resistance, and the like.

The pressure sensitive adhesive layer can be formed by a method of coating a release sheet with a solution of a pressure sensitive adhesive, drying the solution, and transferring the sheet to a surface of a transparent resin layer or a method of directly coating a surface of a transparent resin layer with a solution of a pressure sensitive adhesive and drying the solution.

A solution of a pressure sensitive adhesive is prepared as a 10 to 40 mass % solution obtained by dissolving or dispersing the pressure sensitive adhesive in a solvent such as toluene or ethyl acetate.

As a coating method, a roll coating method such as reverse coating or gravure coating, a spin coating method, a screen coating method, a fountain coating method, a dipping method, or a spray method can be employed.

Examples of the constituent material of the release sheet include appropriate thin paper bodies, for example, synthetic resin films such as polyethylene, polypropylene, and polyethylene terephthalate; rubber sheets; paper; cloth; nonwoven fabrics; nets; foam sheets; and metal foils.

In the present invention, the thickness of an optional pressure sensitive adhesive layer is not particularly limited, but is preferably 3 m to 50 μm, more preferably 4 μm to 40 μm, and still more preferably 5 μm to 30 μm.

[Applications]

The laminate according to the embodiment of the present invention can be used as a polarizing element (polarizing plate). Specifically, the laminate can be used as a linearly polarizing plate or a circularly polarizing plate.

In a case where the laminate according to the embodiment of the present invention does not include an optically anisotropic layer such as the λ/4 plate, the laminate can be used as a linearly polarizing plate. Meanwhile, in a case where the laminate according to the embodiment of the present invention includes the λ/4 plate, the laminate can be used as a circularly polarizing plate.

[Image Display Device]

An image display device according to the embodiment of the present invention includes the above-described laminate according to the embodiment of the present invention.

A display element used in the image display device according to the embodiment of the present invention is not particularly limited, and examples thereof include a liquid crystal cell, an organic electroluminescence (hereinafter, abbreviated as “EL”) display panel, and a plasma display panel.

Among these, a liquid crystal cell or an organic EL display panel is preferable, and a liquid crystal cell is more preferable. That is, in the image display device according to the embodiment of the present invention, a liquid crystal display device obtained by using a liquid crystal cell as a display element or an organic EL display device obtained by using an organic EL display panel as a display element is preferable, and a liquid crystal display device is more preferable.

[Liquid Crystal Display Device]

A liquid crystal display device which is an example of the image display device according to the embodiment of the present invention is a liquid crystal display device that includes the above-described laminate according to the embodiment of the present invention (but does not include a λ/4 plate) and a liquid crystal cell.

In the present invention, among laminates provided on both sides of the liquid crystal cell, it is preferable that the laminate according to the embodiment of the present invention is used as a front-side polarizing element and more preferable that the laminate according to the embodiment of the present invention is used as a front-side polarizing element and a rear-side polarizing element.

Hereinafter, the liquid crystal cell constituting the liquid crystal display device will be described in detail.

<Liquid Crystal Cell>

It is preferable that the liquid crystal cell used for the liquid crystal display device is in a vertical alignment (VA) mode, an optically compensated bend (OCB) mode, an in-plane-switching (IPS) mode, or a twisted nematic (TN) mode, but the present invention is not limited thereto.

In the liquid crystal cell in a TN mode, rod-like liquid crystal molecules (rod-like liquid crystal compound) are substantially horizontally aligned in a case of no voltage application and further twistedly aligned at 60° to 120°. The liquid crystal cell in a TN mode is most frequently used as a color TFT liquid crystal display device and is described in a plurality of documents.

In the liquid crystal cell in a VA mode, rod-like liquid crystal molecules are substantially vertically aligned at the time of no voltage application. The concept of the liquid crystal cell in a VA mode includes (1) liquid crystal cell in a VA mode in a narrow sense where rod-like liquid crystal molecules are aligned substantially vertically in a case of no voltage application and substantially horizontally in a case of voltage application (described in JP1990-176625A (JP-H02-176625A)), (2) liquid crystal cell (in a multi-domain vertical alignment (MVA) mode) (SID97, described in Digest of tech. Papers (proceedings) 28 (1997) 845) in which the VA mode is formed to have multi-domain in order to expand the viewing angle, (3) liquid crystal cell in an axially symmetric aligned microcell (n-ASM) mode in which rod-like liquid crystal molecules are substantially vertically aligned in a case of no voltage application and twistedly multi-domain aligned in a case of voltage application (described in proceedings of Japanese Liquid Crystal Conference, pp. 58 to 59 (1998)), and (4) liquid crystal cell in a SURVIVAL mode (presented at LCD International 98). Further, the liquid crystal cell may be of any of a patterned vertical alignment (PVA) type, a photo-alignment (optical alignment) type, and a polymer-sustained alignment (PSA) type. Details of these modes are described in JP2006-215326A and JP2008-538819A.

In the liquid crystal cell in an IPS mode, rod-like liquid crystal molecules are aligned substantially parallel to the substrate, and the liquid crystal molecules respond planarly through application of an electric field parallel to the substrate surface. In the IPS mode, black display is carried out in a state where no electric field is applied, and absorption axes of a pair of upper and lower polarizing plates are orthogonal to each other. A method of reducing leakage light during black display in an oblique direction and improve the viewing angle using an optical compensation sheet is disclosed in JP1998-054982A (JP-H10-054982A), JP1999-202323A (JP-H11-202323A), JP1997-292522A (JP-H09-292522A), JP1999-133408A (JP-H11-133408A), JP1999-305217A (JP-H11-305217A), and JP1998-307291A (JP-H10-307291A).

[Organic EL Display Device]

As an organic EL display device which is an example of the image display device according to the embodiment of the present invention, an embodiment of a display device including the above-described laminate (here, including a pressure sensitive adhesive layer and a λ/4 plate) according to the embodiment of the present invention and an organic EL display panel in order from the viewing side is suitably exemplified. In this case, the laminate is formed such that a transparent support, and an alignment film, a light absorption anisotropic film, a transparent resin layer, a pressure sensitive adhesive layer, and a λ/4 plate which are provided as necessary are arranged in order from the viewing side.

Further, the organic EL display panel is a display panel formed using an organic EL element having an organic light-emitting layer (organic electroluminescence layer) interposed between electrodes (between a cathode and an anode). The configuration of the organic EL display panel is not particularly limited, and a known configuration is employed.

### EXAMPLES

Hereinafter, the present invention will be described in more detail with reference to examples. Materials, used amounts, ratios, treatment contents, treatment procedures, and the like described in the following examples can be appropriately changed without departing from the spirit of the present invention. Therefore, the scope of the present invention should not be limitatively interpreted by the following examples.

### Example 1

<Preparation of Transparent Support 1>

A TAC base material (TG40, manufactured by FUJIFILM Corporation) having a thickness of 40 μm was continuously coated with an alignment film coating solution having the following composition using a #8 wire bar. Thereafter, the base material was dried with warm air at 100° C. for 2 minutes, thereby obtaining a transparent support 1 in which a polyvinyl alcohol (PVA) alignment film having a thickness of 0.8 μm was formed on the TAC base material.

Further, modified polyvinyl alcohol was added to the alignment film coating solution such that the concentration of solid contents was set to 4 wt %.

Composition of alignment film coating solution

| Modified polyvinyl alcohol shown below | | |
|---|---|---|
| Water: | 70 | parts by mass |
| Methanol: | 30 | parts by mass |

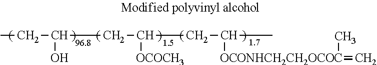

<Formation of Alignment Film 1>

41.6 parts by mass of butoxyethanol, 41.6 parts by mass of dipropylene glycol monomethyl ether, and 15.8 parts by mass of pure water were added to 1 part by mass of a photo-alignment material E-1 having the following structure, and the obtained solution was filtered using a 0.45 μm membrane filter under pressure, thereby preparing a composition 1 for forming an alignment film.

Thereafter, the PVA alignment film on the transparent support 1 was coated with the obtained composition 1 for forming an alignment film and dried at 60° C. for 1 minute. Next, the obtained coating film was irradiated with linearly polarized ultraviolet rays (illuminance of 4.5 mW, irradiation dose of 500 mJ/cm²) using a polarized ultraviolet ray exposure device, thereby forming an alignment film 1. In addition, the alignment film 1 is noted as “azo (E-1)” in Table 1.

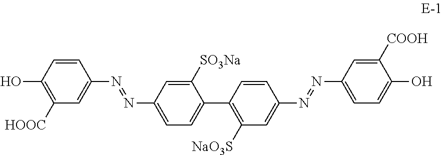

<Formation of Light Absorption Anisotropic Film 1>

The obtained alignment film 1 was continuously coated with the following composition 1 for forming a light absorption anisotropic film (noted as the “composition 1” in Table 1) using a #4 wire bar, thereby forming a coating film 1.

Next, the coating film 1 was heated at 140° C. for 90 seconds, and the resulting coating film 1 was cooled to room temperature (23° C.).

Thereafter, the coating film 1 was heated at 80° C. for 60 seconds and cooled to room temperature again.

Thereafter, the coating film 1 was irradiated under an irradiation condition of an illuminance of 28 mW/cm² for 60 seconds using a high-pressure mercury lamp, thereby preparing a light absorption anisotropic film 1 on the alignment film 1.

Composition of composition 1 for forming light absorption anisotropic film

| | | |
|---|---|---|
| Yellow azo dye Y-1 shown below: | 0.23 | parts by mass |
| Magenta azo dye M-1 shown below: | 0.21 | parts by mass |
| Cyanazo dye C-1 shown below: | 0.46 | parts by mass |
| Polymer liquid crystal compound P-1 shown below: | 4.06 | parts by mass |
| Polymerization initiator IRGACURE, 819 (manufactured by BASF SE): | 0.043 | parts by mass |
| Interface modifier F-1 shown below: | 0.039 | parts by mass |
| Cyclopentanone: | 66.50 | parts by mass |
| Tetrahydrofuran: | 28.50 | parts by mass |

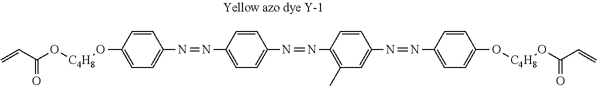

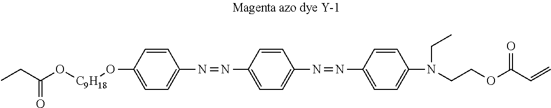

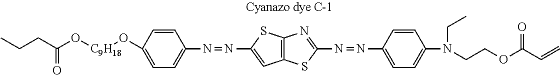

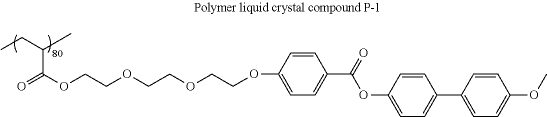

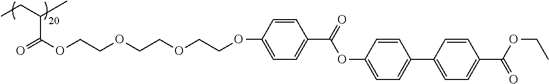

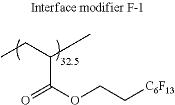

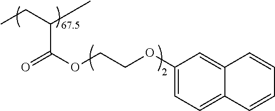

<Formation of Liquid Crystal Layer A>

The obtained light absorption anisotropic film 1 was continuously coated with the following composition A for forming a liquid crystal layer (noted as the “composition A” in Table 1) using a #3 wire bar, thereby forming a coating film 1.

Next, the coating film 1 was dried at room temperature and irradiated under an irradiation condition of an illuminance of 28 mW/cm² for 10 seconds using a high-pressure mercury lamp, thereby preparing a liquid crystal layer A on the light absorption anisotropic film 1.

Composition of composition A for
forming liquid crystal layer

| Mixture L1 of rod-like liquid crystal | 3.28 | parts by mass |
|---|---|---|
| compounds shown below: | | |
| Modified trimethylolpropane triacrylate | 0.13 | parts by mass |
| shown below: | | |
| Photopolymerization initiator I-1 shown | 0.20 | parts by mass |
| below: | | |
| Interface modifier F1 shown below: | 0.14 | parts by mass |
| Methyl ethyl ketone: | 371 | parts by mass |

Mixture L1 of rod-like liquid crystal positive compounds (the numerical values in the following formulae are on a % by mass basis, and R represents a group bonded with respect to an oxygen atom).

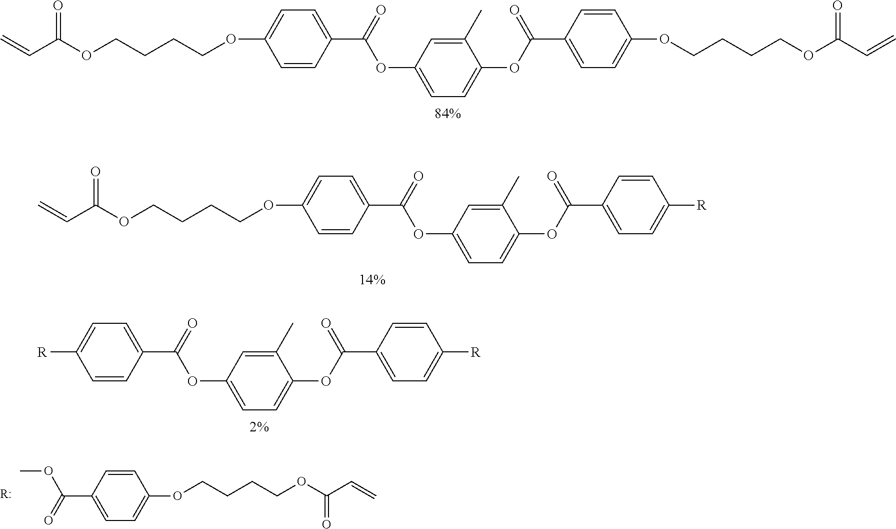

Modified Trimethylolpropane Triacrylate

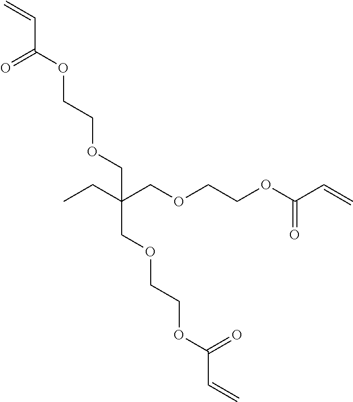 [SMILES: C=CC(=O)OCCOCC(CC)(COCCOC(=O)C=C)COCCOC(=O)C=C]

Photopolymerization initiator I-1 shown below

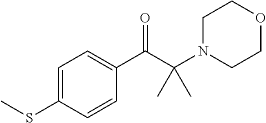 [SMILES: CSc1ccc(C(=O)C(C)(C)N2CCOCC2)cc1]

<Formation of Barrier Layer 1>

The liquid crystal layer A was continuously coated with the following composition 1 for forming a barrier layer using a #2 wire bar and dried at 40° C. for 90 seconds.

Next, the layer was irradiated under an irradiation condition of an illuminance of 30 mW/cm² for 10 seconds using a high-pressure mercury lamp so that the resin composition was cured, thereby preparing a laminate in which a barrier layer 1 was formed on the liquid crystal layer A.

The cross section of the barrier layer 1 was cut using a microtome cutting machine, and the film thickness thereof was measured by observation with a scanning electron microscope (SEM), and the film thickness was approximately 1.8 μm.

Composition 1 for forming barrier layer

| | | |
|---|---|---|
| CEL2021P (manufactured by Daicel Corporation) shown below: | 54 | parts by mass |
| IRGACURE 127 (manufactured by BASF SE): | 3 | parts by mass |
| CPI-100P (propylene carbonate solution) shown below: | 3 | parts by mass |
| Organo silica sol MEK-EC-2130Y (manufactured by Nissan Chemical Corporation): | 300 | parts by mass |
| MEGAFACE RS-90 (manufactured by DIC Corporation): | 7.5 | parts by mass |
| Methyl ethyl ketone (MEK): | 133 | parts by mass |

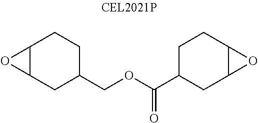 [SMILES: O=C(OCC1CCC2OC2C1)C1CCC2OC2C1]

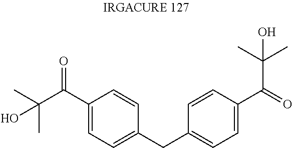 [SMILES: CC(C)(O)C(=O)c1ccc(Cc2ccc(C(=O)C(C)(C)O)cc2)cc1]

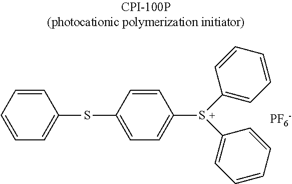

### Example 2

A laminate of Example 2 was obtained according to the same method as in Example 1 except that the composition 1 for forming a light absorption anisotropic film was changed to the following composition 2 for forming a light absorption anisotropic film in the formation of the light absorption anisotropic film.

Composition of composition 2 for forming light absorption anisotropic film

| | | |
|---|---|---|
| Yellow azo dye Y-1 shown below: | 0.13 | parts by mass |
| Magenta azo dye M-2 shown below: | 0.21 | parts by mass |
| Cyanazo dye C-2 shown below: | 0.56 | parts by mass |
| Polymer liquid crystal compound P-2 shown below: | 4.03 | parts by mass |
| Polymerization initiator IRGACURE 819 (manufactured by BASF SE): | 0.043 | parts by mass |
| Interface modifier Fl shown below: | 0.039 | parts by mass |
| Cyclopentanone: | 66.50 | parts by mass |
| Tetrahydrofuran: | 28.50 | parts by mass |

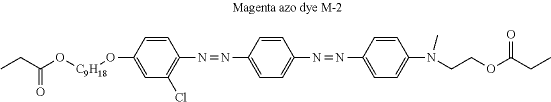

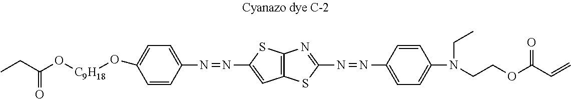

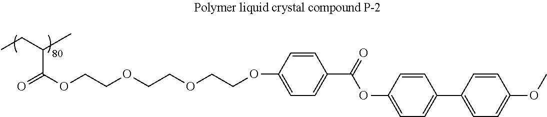

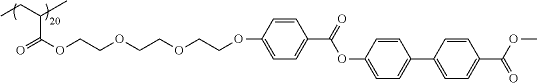

### Example 3

A laminate of Example 3 was obtained according to the same method as in Example 1 except that the composition 1 for forming a light absorption anisotropic film was changed to the following composition 3 for forming a light absorption anisotropic film in the formation of the light absorption anisotropic film.

Composition of composition 3 for forming light absorption anisotropic film

| | | |
|---|---|---|
| Yellow azo dye Y-2 shown below: | 0.23 | parts by mass |
| Magenta azo dye M-3 shown below: | 0.21 | parts by mass |
| Cyanazo dye C-3 shown below: | 0.46 | parts by mass |
| Polymer liquid crystal compound P-2 shown below: | 4.03 | parts by mass |
| Polymerization initiator IRGACURE 819 (manufactured by BASF SE): | 0.043 | parts by mass |
| Interface modifier Fl shown below: | 0.039 | parts by mass |
| Cyclopentanone: | 66.50 | parts by mass |
| Tetrahydrofuran: | 28.50 | parts by mass |

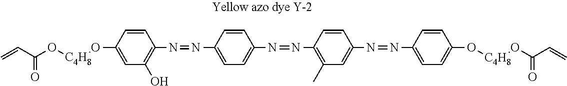

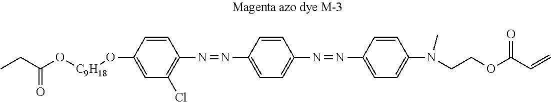

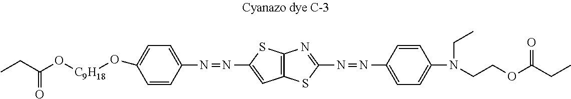

### Examples 4 and 5

Laminates of Examples 4 and 5 were obtained according to the same method as in Example 2 except that the solid content was adjusted and the coating was performed such that the film thickness of the liquid crystal layer A was set to the film thickness listed in Table 1 in the formation of the liquid crystal layer.

### Example 6

A laminate of Example 6 was obtained according to the same method as in Example 1 except that an alignment film 2 formed by the following method was used in place of the alignment film 1.

<Formation of Alignment Film 2>

(Synthesis of Polymer E-2)

A reaction container provided with a stirrer, a thermometer, a dropping funnel, and a reflux cooling tube was charged with 100.0 parts by mass of 2-(3,4-epoxycyclohexyl)ethyltrimethoxysilane, 500 parts by mass of methyl isobutyl ketone, and 10.0 parts by mass of triethylamine, and the mixture was stirred at room temperature. Next, 100 parts by mass of deionized water was added dropwise to the mixture for 30 minutes using the dropping funnel, and the obtained mixture was allowed to react at 80° C. for 6 hours while being mixed under reflux. After completion of the reaction, an organic phase was taken out from the mixture, and the organic phase was washed until water after being washed with a 0.2 mass % ammonium nitrate aqueous solution was neutral. Thereafter, the solvent and water were distilled off from the obtained organic phase under reduced pressure, thereby obtaining polyorganosiloxane containing an epoxy group in the form of a viscous and transparent liquid.

The nuclear magnetic resonance (¹H-NMR) analysis was performed on the polyorganosiloxane containing an epoxy group. As the result, it was confirmed that a peak based on an oxiranyl group was obtained around a chemical shift (δ) of 3.2 ppm according to the theoretical strength, and side reactions of the epoxy group did not occur during the reaction. The weight-average molecular weight Mw of the polyorganosiloxane containing an epoxy group was 2200 and the epoxy equivalent thereof was 186 g/mol.

Next, a 100 mL three-neck flask was charged with 10.1 parts by mass of the polyorganosiloxane containing an epoxy group obtained in the above-described manner, 0.5 parts by mass of acrylic group-containing carboxylic acid (trade name, “ARONIX M-5300”, manufactured by Toagosei Co., Ltd., acrylic acid ω-carboxypolycaprolactone (polymerization degree n of approximately 2)), 20 parts by mass of butyl acetate, 1.5 parts by mass of a cinnamic acid derivative obtained by the method of Synthesis Example 1 of JP2015-026050A, and 0.3 parts by mass of tetrabutylammonium bromide, and the obtained reaction solution was stirred at 90° C. for 12 hours. After the mixture was stirred, the mixture was diluted with butyl acetate whose amount (mass) was set to be the same as the amount of the mixture, and the diluted mixture was washed with water three times. An operation of concentrating the obtained mixture and diluting the mixture with butyl acetate was repeated twice to finally obtain a solution containing polyorganosiloxane (polymer E-2 shown below) containing a photo-aligned group. The weight-average molecular weight Mw of the polymer E-2 was 9000. Further, as the result of ¹H-NMR, the content of the component containing a cinnamate group in the polymer E-2 was 23.7% by mass.

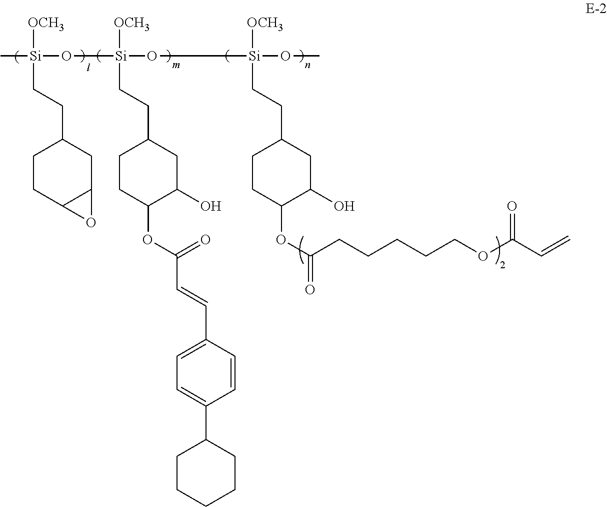

(Preparation of Composition 2 for Forming Alignment Film)

The following components were mixed to prepare the composition 2 for forming an alignment film.

Composition of composition 2 for forming alignment film

| Polymer E-2 described above: | 10.67 | parts by mass |
|---|---|---|
| Low-molecular-weight compound R-1 | 5.17 | parts by mass |
| shown below: | | |
| Additive (B-1) shown below: | 0.53 | parts by mass |
| Butyl acetate: | 8287.37 | parts by mass |
| Propylene glycol monomethyl ether acetate: | 2071.85 | parts by mass |

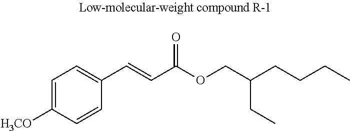 [SMILES: CCCCC(CC)COC(=O)/C=C/c1ccc(OC)cc1]

Additive (B-1): TA-60B (manufactured by San-Apro Ltd.) (see structural formula below)

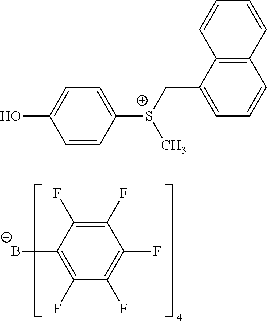

A TAC support was coated with the composition 2 for forming an alignment film using a spin coating method, and the support coated with the composition 2 for forming an alignment film was dried on a hot plate at 80° C. for 5 minutes so that the solvent was removed, thereby forming a coating film.

The obtained coating film was irradiated with polarized ultraviolet rays (25 mJ/cm², ultrahigh-pressure mercury lamp) to form an alignment film 2. Further, the alignment film 2 is noted as “cinnamoyl (E-2)” in Table 1.

### Example 7

A laminate of Example 7 was obtained according to the same method as in Example 1 except that an alignment film 3 formed by the following method was used in place of the alignment film 1.

<Formation of Alignment Film 3>

A dried polyethylene terephthalate (PET) support was coated with the composition 3 for forming an alignment film using a #4 bar, the applied composition 3 for forming an alignment film was dried at 80° C. for 15 minutes and heated at 250° C. for 1 hour, thereby forming a coating film on the PET support.

The obtained coating film was irradiated with polarized ultraviolet rays (1 J/cm², ultrahigh-pressure mercury lamp) once, thereby forming an alignment film 3 on the PET support. Further, the alignment film 3 is noted as “polyimide” in Table 1.

Composition of composition 3 for
forming alignment film

| | |
|---|---|
| Material of polyimide alignment | 2.0 parts by mass |
| film (SE-130, Nissan Chemical | |
| Corporation): | |
| N-methylpyrrolidone: | 98.0 parts by mass |

### Example 8

A laminate of Example 8 was obtained according to the same method as in Example 1 except that the composition A for forming a liquid crystal layer was changed to the following composition B for forming a liquid crystal layer in the formation of the liquid crystal layer.

Composition of composition B for forming
liquid crystal layer

| Mixture L1 of rod-like liquid crystal | 1.88 | parts by mass |
|---|---|---|
| compounds described above: | | |
| Modified trimethylolpropane | 2.16 | parts by mass |
| triacrylate described above: | | |
| Photopolymerization initiator I-1 | 0.20 | parts by mass |
| described above: | | |
| Interface modifier F1 described | 0.14 | parts by mass |
| above: | | |
| Methyl ethyl ketone: | 434 | parts by mass |

### Example 9

A laminate of Example 9 was obtained according to the same method as in Example 1 except that the composition A for forming a liquid crystal layer was changed to the following composition C for forming a liquid crystal layer in the formation of the liquid crystal layer.

Composition of composition C for forming liquid crystal layer

| | | |
|---|---|---|
| Rod-like liquid crystal compound (L2) shown below: | 1.0 | parts by mass |
| Modified trimethylolpropane triacrylate described above: | 0.1 | parts by mass |
| Photopolymerization initiator I-1 described above: | 0.06 | parts by mass |
| Interface modifier F1 described above: | 0.044 | parts by mass |
| Methyl ethyl ketone: | 113.8 | parts by mass |

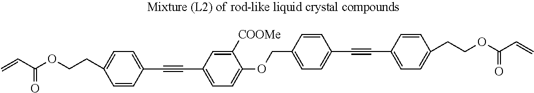 [SMILES: C=CC(=O)OCCc1ccc(C#Cc2ccc(COc3ccc(C#Cc4ccc(CCOC(=O)C=C)cc4)cc3C(=O)OC)cc2)cc1]

### Example 10

<Synthesis of Liquid Crystal Compound>

A liquid crystal compound (1-6) represented by Formula (1-6) was synthesized by the method described in Recl. Trav. Chim. Pays-Bas, 115, 321 to 328 (1996), Lub et al.

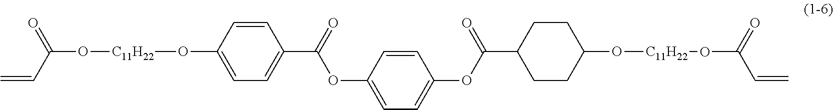

Next, a liquid crystal compound (1-7) represented by Formula (1-7) was synthesized with reference to the method of synthesizing the compound (1-6) described above.

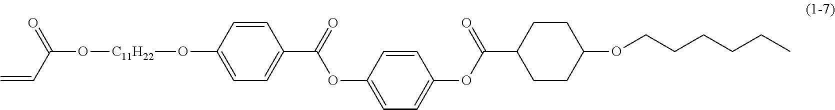

<Preparation of Composition 4 for Forming Light Absorption Anisotropic Film>

The following components were mixed and stirred at 80° C. for 1 hour, thereby preparing a composition 4 for forming a light absorption anisotropic film (noted as the “composition 4” in Table 1).

Composition of composition 4 for forming light
absorption anisotropic film

| | |
|---|---|
| Liquid crystal compound (1-6) described above: | 50 parts by mass |
| Liquid crystal compound (1-7) described above: | 50 parts by mass |
| Azo dye (G-205; manufactured by Hayashibara | 25 parts by mass |
| Co., Ltd.): | |
| Polymerization initiator IRGACURE 369 | 6 parts by mass |
| (manufactured by BASF SE): | |
| Polyaerylate compound (BYK-361N, | 1.2 parts by mass |
| manufactured by BYK-Chemie GmbH): | |
| Cyclopentanone: | 250 parts by mass |

A laminate of Example 10 was obtained according to the same method as in Example 1 except that the composition 1 for forming a light absorption anisotropic film was changed to the following composition 4 for forming a light absorption anisotropic film in the formation of the light absorption anisotropic film.

### Example 11

The transparent support 1 prepared in Example 1 was coated with the composition 2 for forming an alignment film used in Example 6 according to a spin coating method, and the support coated with the composition 2 for forming an alignment film was dried on a hot plate at 80° C. for 5 minutes so that the solvent was removed, thereby forming a coating film. The obtained coating film was irradiated with polarized ultraviolet rays (25 mJ/cm², ultrahigh-pressure mercury lamp) to form an alignment film 2. Further, the alignment film 2 is noted as “cinnamoyl (E-2)” in Table 1.

<Formation of Liquid Crystal Layer A>

Next, the alignment film 2 was continuously coated with the composition A for forming a liquid crystal layer (noted as the “composition A” in Table 1) used in Example 1 with a #3 wire bar, thereby forming a coating film 1.

Next, the coating film 1 was dried at room temperature and irradiated under an irradiation condition of an illuminance of 28 mW/cm² for 10 seconds using a high-pressure mercury lamp, thereby preparing a liquid crystal layer A on the alignment film 2.

<Formation of Light Absorption Anisotropic Film 2>

The obtained liquid crystal layer A was continuously coated with the composition 2 for forming a light absorption anisotropic film (noted as the “composition 2” in Table 1) using a #4 wire bar, thereby forming a coating film 1.

Next, the coating film 1 was heated at 140° C. for 90 seconds, and the resulting coating film 1 was cooled to room temperature (23° C.).

Thereafter, the coating film 1 was heated at 80° C. for 60 seconds and cooled to room temperature again.

Thereafter, the coating film 1 was irradiated under an irradiation condition of an illuminance of 28 mW/cm² for 60 seconds using a high-pressure mercury lamp, thereby preparing a light absorption anisotropic film 2 on the liquid crystal layer A.

<Formation of Barrier Layer>

The light absorption anisotropic film 2 was continuously coated with the composition 1 for forming a barrier layer using a #2 wire bar and dried at 40° C. for 90 seconds in the same manner as in Example 1.

Thereafter, the film was irradiated under an irradiation condition of an illuminance of 30 mW/cm² for 10 seconds using a high-pressure mercury lamp so that the resin composition was cured, thereby preparing a laminate in which a barrier layer 1 was formed on the light absorption anisotropic film 2.

### Example 12

A TAC base material (TG40, manufactured by FUJIFILM Corporation) having a thickness of 40 μm was continuously coated with an alignment film coating solution 9 having the following composition using a #8 wire bar. The solution was dried with warm air at 100° C. for 2 minutes, thereby obtaining an alignment film having a thickness of 0.8 μm.

Further, modified polyvinyl alcohol (modified PVA) was added to the alignment film coating solution such that the concentration of solid contents was set to 4% by mass. The alignment film prepared in the above-described manner was subjected to a rubbing treatment to form an alignment film. Further, the alignment film after the completion of the rubbing treatment is noted as “PVA rubbing” in Table 1.

Composition of alignment film coating solution

| Modified polyvinyl alcohol shown below | | |
|---|---|---|
| Water: | 70 | parts by mass |
| Methanol: | 30 | parts by mass |

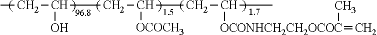

The alignment film after the completion of the rubbing treatment was continuously coated with the composition B for forming a liquid crystal layer (noted as the “composition B” in Table 1) used in Example 8 with a #3 wire bar, thereby forming a coating film 1.

Next, the coating film 1 was dried at room temperature and irradiated under an irradiation condition of an illuminance of 28 mW/cm² for 10 seconds using a high-pressure mercury lamp, thereby forming a liquid crystal layer B on the alignment film.

Further, the obtained liquid crystal layer B was continuously coated with the composition 2 for forming a light absorption anisotropic film (noted as the “composition 2” in Table 1) using a #4 wire bar, thereby forming a coating film 1.

Next, the coating film 1 was heated at 140° C. for 90 seconds, and the resulting coating film 1 was cooled to room temperature (23° C.). Thereafter, the coating film 1 was heated at 80° C. for 60 seconds and cooled to room temperature again.

Thereafter, the coating film 1 was irradiated under an irradiation condition of an illuminance of 28 mW/cm² for 60 seconds using a high-pressure mercury lamp, thereby preparing a light absorption anisotropic film 2 on the liquid crystal layer B.

<Formation of Barrier Layer>

The light absorption anisotropic film 2 was continuously coated with the composition 1 for forming a barrier layer using a #2 wire bar and dried at 40° C. for 90 seconds in the same manner as in Example 1.

Thereafter, the film was irradiated under an irradiation condition of an illuminance of 30 mW/cm² for 10 seconds using a high-pressure mercury lamp so that the resin composition was cured, thereby preparing a laminate in which a barrier layer A was formed on the light absorption anisotropic film 2.

### Example 13

The transparent support 1 prepared in Example 1 was coated with the composition 2 for forming an alignment film used in Example 6 according to a spin coating method, and the support coated with the composition 2 for forming an alignment film was dried on a hot plate at 80° C. for 5 minutes so that the solvent was removed, thereby forming a coating film. The obtained coating film was irradiated with polarized ultraviolet rays (25 mJ/cm², ultrahigh-pressure mercury lamp) to form an alignment film 2.

<Formation of Liquid Crystal Layer A1>

Next, the alignment film 2 was continuously coated with the composition A for forming a liquid crystal layer used in Example 1 with a #3 wire bar, thereby forming a coating film 1.

Next, the coating film 1 was dried at room temperature and irradiated under an irradiation condition of an illuminance of 28 mW/cm² for 10 seconds using a high-pressure mercury lamp, thereby preparing a liquid crystal layer A1 on the alignment film 2.

<Formation of Light Absorption Anisotropic Film 2>

The obtained liquid crystal layer A1 was continuously coated with the composition 2 for forming a light absorption anisotropic film using a #4 wire bar, thereby forming a coating film 1.

Next, the coating film 1 was heated at 140° C. for 90 seconds, and the resulting coating film 1 was cooled to room temperature (23° C.).

Thereafter, the coating film 1 was heated at 80° C. for 60 seconds and cooled to room temperature again.

Thereafter, the coating film 1 was irradiated under an irradiation condition of an illuminance of 28 mW/cm² for 60 seconds using a high-pressure mercury lamp, thereby preparing a light absorption anisotropic film 2 on the liquid crystal layer A1.

<Formation of Liquid Crystal Layer A2>

Next, the light absorption anisotropic film 2 was continuously coated with the composition A for forming a liquid crystal layer used in Example 1 with a #3 wire bar, thereby forming a coating film 2.

Next, the coating film 2 was dried at room temperature and irradiated under an irradiation condition of an illuminance of 28 mW/cm² for 10 seconds using a high-pressure mercury lamp, thereby preparing a liquid crystal layer A2 on the light absorption anisotropic film 2.

<Formation of Barrier Layer>

The liquid crystal layer A2 was continuously coated with the composition 1 for forming a barrier layer using a #2 wire bar and dried at 40° C. for 90 seconds in the same manner as in Example 1.

Thereafter, the layer was irradiated under an irradiation condition of an illuminance of 30 mW/cm² for 10 seconds using a high-pressure mercury lamp so that the resin composition was cured, thereby preparing a laminate in which a barrier layer 1 was formed on the liquid crystal layer A2.

### Comparative Example 1

A laminate was prepared in the same manner as in Example 1 except that the liquid crystal layer was not formed.

### Comparative Example 2

A laminate was prepared in the same manner as in Example 11 except that the liquid crystal layer was not formed.

### Comparative Example 3

A laminate of Comparative Example 3 was obtained according to the same method as in Example 1 except that the solid content was adjusted and the coating was performed such that the film thickness of the liquid crystal layer 1 was set to the film thickness listed in Table 1 in the formation of the liquid crystal layer.

### Comparative Example 4

A laminate of Comparative Example 4 was obtained according to the same method as in Example 1 except that the composition A for forming a liquid crystal layer was changed to the following resin composition D (noted as the “composition D” in Table 1) in the formation of the liquid crystal layer.

Composition of resin composition D

| Modified trimethylolpropane triaerytate | 3.41 | parts by mass |
|---|---|---|
| described above: | | |
| Photopolymerization initiator I-1 | 0.40 | parts by mass |
| described above: | | |
| Interface modifier F1 described above: | 0.14 | parts by mass |
| Methyl ethyl ketone: | 371 | parts by mass |

### Comparative Example 5

A laminate of Comparative Example 5 was obtained according to the same method as in Example 1 except that the temperature of the coating film was changed to 90° C. during the irradiation with a high-pressure mercury lamp and the liquid crystal layer was formed without aligning the liquid crystal compound in the formation of the liquid crystal layer.

### Comparative Example 6

<Formation of Liquid Crystal Layer>

The transparent support 1 of Example 1 was coated with the composition A for forming a liquid crystal layer using a spin coating method, thereby forming a coating film 1. Next, the coating film 1 was dried at room temperature and irradiated under an irradiation condition of an illuminance of 28 mW/cm² for 10 seconds using a high-pressure mercury lamp, thereby preparing a liquid crystal layer A on the transparent support.

The cross section of the liquid crystal layer A was cut using a microtome cutting machine, and the film thickness thereof was measured by observation with a scanning electron microscope (SEM), and the film thickness was approximately 600 nm.

Next, an alignment film and a light absorption anisotropic film were formed on the transparent support 1 in the same manner as in Example 1.

The light absorption anisotropic film prepared in the above-described manner was coated with a pressure sensitive adhesive (SK-2057, manufactured by Soken Chemical & Engineering Co., Ltd.) to form a pressure sensitive adhesive layer, and the pressure sensitive adhesive layer was bonded to the liquid crystal layer A on the transparent support such that the angle between the absorption axis of the light absorption anisotropic film and the slow axis of the liquid crystal layer was set to 45°, thereby forming a laminate of Comparative Example 6.

[Preparation of Circularly Polarizing Plate]

The light absorption anisotropic film (the barrier layer in a case where a barrier layer was formed) of each laminate prepared in the above-described manner was coated with a pressure sensitive adhesive (SK-2057, manufactured by Soken Chemical & Engineering Co., Ltd.) to form a pressure sensitive adhesive layer, PURE ACE WR (manufactured by Teijin Ltd.) was bonded thereto as a λ/4 plate, thereby preparing a circularly polarizing plate.

GALAXY S5 (manufactured by Samsung Electronics Co., Ltd.) equipped with an organic EL panel (organic EL display element) was disassembled, the touch panel provided with a circularly polarizing plate was peeled off from the organic EL display device, and the circularly polarizing plate was further peeled off from the touch panel so that the organic EL display element, the touch panel, and the circularly polarizing plate were isolated from each other. Subsequently, the isolated touch panel was bonded to the organic EL display element again, and the prepared circularly polarizing plate was further bonded onto the touch panel such that air did not enter therein, thereby preparing an organic EL display device.

[Display Performance]

The visibility and display quality of the prepared organic EL display device were evaluated under bright light. The display screen of the display device was set to be displayed in black, and reflected light in a case of projecting fluorescent light on the front surface at a polar angle of 45 degrees was observed. The display performance was evaluated based on the following standards. The evaluation results are collectively listed in Table 1.

6: The screen was displayed in black and coloring was not visually recognized

5: Coloring was slightly visually recognized, but the reflectivity was extremely low

4: Coloring was slightly visually recognized, but the reflectivity was low

3: Coloring was slightly visually recognized, and the reflectivity was high

2: Coloring was visually recognized, and the reflectivity was high

1: Coloring was clearly visually recognized, and the reflectivity was extremely high

[Moisture and Heat Resistance]

The prepared organic EL display device was allowed to be aged for 500 hours in an environment of 60° C. and a relative humidity of 90%. Thereafter, the visibility and the display quality of the obtained display device were evaluated under bright light. The display screen of the display device was set to be displayed in black, and reflected light in a case of projecting fluorescent light on the front surface at a polar angle of 45 degrees was observed. The display performance was evaluated based on the following standards. The evaluation results are collectively listed in Table 1.

6: The screen was displayed in black and coloring was not visually recognized

5: Coloring was slightly visually recognized, but the reflectivity was extremely low

4: Coloring was slightly visually recognized, but the reflectivity was low

3: Coloring was slightly visually recognized, and the reflectivity was high

2: Coloring was visually recognized, and the reflectivity was high

1: Coloring was clearly visually recognized, and the reflectivity was extremely high

TABLE 1

| | | | Light absorption anisotropic film | | | | |
|---|---|---|---|---|---|---|---|
| | | | | | | Refractive | Liquid |
| | | | | | Average | index | crystal layer |
| | Layer | Alignment | | Degree of | refractive | anisotropy | and the like |
| | configuration | film | Composition | alignment | index N₅₅₀ | Δn | Composition |
| Example 1 | Configuration A | Azo (E-1) | Composition 1 | 0.970 | 1.65 | 0.2 | Composition A |
| Example 2 | Configuration A | Azo (E-1) | Composition 2 | 0.975 | 1.65 | 0.2 | Composition A |
| Example 3 | Configuration A | Azo (E-1) | Composition 3 | 0.970 | 1.65 | 0.2 | Composition A |
| Example 4 | Configuration A | Azo (E-1) | Cornposition 2 | 0.975 | 1.65 | 0.2 | Composition A |
| Example 5 | Configuration A | Azo (E-1) | Composition 2 | 0.975 | 1.65 | 0.2 | Composition A |
| Example 6 | Configuration A | Cinnamoyl | Composition 1 | 0.970 | 1.65 | 0.2 | Composition A |
| | | (E-2) | | | | | |
| Example 7 | Configuration A | Polyimide | Composition 1 | 0.970 | 1.65 | 0.2 | Composition A |
| Example 8 | Configuration A | Azo (E-1) | Composition 2 | 0.975 | 1.65 | 0.2 | Composition B |
| Example 9 | Configuration A | Azo (E-1) | Composition 2 | 0.975 | 1.65 | 0.2 | Composition C |
| Example 10 | Configuration A | Azo (E-1) | Composition 4 | 0.930 | 1.60 | 0.15 | Composition A |
| Example 11 | Configuration B | Cinnamoyl | Composition 2 | 0.970 | 1.65 | 0.2 | Composition A |
| | | (E-2) | | | | | |
| Example 12 | Configuration B | PVA rubbing | Composition 2 | 0.970 | 1.60 | 0.1 | Composition B |
| Example 13 | Configuration C | Cinnamoyl | Composition 2 | 0.970 | 1.65 | 0.2 | Composition A |
| | | (E-2) | | | | | |
| Comparative | Configuration A | Azo (E-1) | Composition 1 | 0.970 | 1.65 | 0.2 | Not available |
| Example 1 | | | | | | | |
| Comparative | Configuration B | Cinnamoyl | Composition 2 | 0.970 | 1.65 | 0.2 | Not available |
| Example 2 | | (E-2) | | | | | |
| Comparative | Configuration A | Azo (E-1) | Composition 1 | 0.970 | 1.65 | 0.2 | Composition A |
| Example 3 | | | | | | | |
| Comparative | Configuration A | Azo (E-1) | Composition 1 | 0.970 | 1.65 | 0.2 | Composition D |
| Example 4 | | | | | | | |
| Comparative | Configuration A | Azo (E-1) | Composition 1 | 0.970 | 1.65 | 0.2 | Composition A |
| Example 5 | | | | | | | |
| Comparative | Configuration D | Azo (E-1) | Composition 1 | 0.970 | 1.65 | 0.2 | Composition A |
| Example 6 | | | | | | | |
| | | Liquid crystal layer and the like | | | | | |
| | | | | Refractive | | | |
| | | | Average | index | | Display | Moisture |
| | | Film | refractive | anisotropy | Formed | perform- | anf heat |
| | | thickness | index N₅₅₀ | Δn | angle * | ance | durability |
| | Example 1 | 45 nm | 1.66 | 0.15 | 0 | 5 | 4 |
| | Example 2 | 45 nm | 1.66 | 0.15 | 0 | 6 | 5 |
| | Example 3 | 45 nm | 1.66 | 0.15 | 0 | 5 | 4 |
| | Example 4 | 25 nm | 1.66 | 0.15 | 0 | 6 | 5 |
| | Example 5 | 200 nm | 1.66 | 0.15 | 0 | 5 | 5 |
| | Example 6 | 45 nm | 1.66 | 0.15 | 0 | 5 | 5 |
| | Example 7 | 45 nm | 1.66 | 0.15 | 0 | 5 | 5 |
| | Example 8 | 45 nm | 1.58 | 0.10 | 0 | 5 | 4 |
| | Example 9 | 45 nm | 1.75 | 0.25 | 0 | 6 | 5 |
| | Example 10 | 45 nm | 1.66 | 0.15 | 0 | 4 | 3 |
| | Example 11 | 45 nm | 1.66 | 0.15 | 0 | 5 | 4 |
| | Example 12 | 45 nm | 1.58 | 0.10 | 0 | 5 | 4 |
| | Example 13 | 45 nm | 1.66 | 0.15 | 0 | 6 | 6 |
| | Comparative | Not | Not | Not | — | 3 | 1 |
| | Example 1 | available | available | available | | | |
| | Comparative | Not | Not | Not | — | 3 | 3 |
| | Example 2 | available | available | available | | | |
| | Comparative | 350 nm | 1.60 | 0.15 | 0 | 3 | 2 |
| | Example 3 | | | | | | |
| | Comparative | 45 nm | 1.53 | 0 | 0 | 1 | 1 |
| | Example 4 | | | | | | |
| | Comparative | 45 nm | 1.66 | 0 | 0 | 2 | 1 |
| | Example 5 | | | | | | |
| | Comparative | 600 nm | 1.66 | 0.15 | 45 | 5 | 1 |
| | Example 6 | | | | | | |

* The angle between the absorption axis of the light absorption anisotropic film and the slow axis of the liquid crystal layer

As listed in Table 1, it was found that the display performance was degraded in a case where the laminate having no liquid crystal layer was used in the image display device, and the moisture and heat resistance was also degraded in a case where the laminate including an azo-based alignment film was used in the image display device (Comparative Examples 1 and 2).

Further, it was also found that the display performance and the moisture and heat resistance were degraded in a case where the laminate having a liquid crystal layer with a thickness of greater than 300 nm was used in the image display device (Comparative Example 3).

Further, it was also found that the display performance and the moisture and heat resistance were degraded in a case where the laminate having a resin layer in place of a liquid crystal layer and the laminate having a liquid crystal layer without aligning a liquid crystal compound (without having a slow axis) were respectively used in the image display device (Comparative Examples 4 and 5).

Further, it was found that the moisture and heat resistance was degraded in a case where the laminate formed such that the angle between the absorption axis of the light absorption anisotropic film and the slow axis of the liquid crystal layer was set to 45° was used in the image display device (Comparative Example 6).

On the contrary, it was found that the display performance and the moisture and heat durability were excellent in a case where each laminate having a liquid crystal layer with a thickness of 300 nm or less and formed such that the absorption axis of the light absorption anisotropic film and the slow axis of the liquid crystal layer were parallel to each other was used in the image display device (Examples 1 to 13).

### EXPLANATION OF REFERENCES

100, 200, 300, 400: laminate
12: transparent support
14: alignment film
16: light absorption anisotropic film
18: liquid crystal layer
20: second liquid crystal layer
30: barrier layer
40: optically anisotropic layer

What is claimed is:

1. A laminate comprising:
a light absorption anisotropic film; and
a liquid crystal layer which is adjacent to the light absorption anisotropic film,
wherein the light absorption anisotropic film is a film formed of a composition containing a dichroic material,
the liquid crystal layer is a layer which contains a liquid crystal compound is aligned therein and has a thickness of 300 nm or less, and
an absorption axis of the light absorption anisotropic film and a slow axis of the liquid crystal layer are parallel to each other.

2. The laminate according to claim 1,
wherein an average refractive index n₅₅₀ of the liquid crystal layer at a wavelength of 550 nm is 1.50 to 1.75.

3. The laminate according to claim 1,
wherein an in-plane refractive index anisotropy Δn of the liquid crystal layer at a wavelength of 550 nm is 0.03 or greater.

4. The laminate according to claim 1, further comprising:
a transparent support; and
an alignment film,
wherein the transparent support, the alignment film, the light absorption anisotropic film, and the liquid crystal layer are provided in order.

5. The laminate according to claim 1, further comprising:
a transparent support; and
an alignment film,
wherein the transparent support, the alignment film, the liquid crystal layer, and the light absorption anisotropic film are provided in order.

6. The laminate according to claim 1, further comprising:
a transparent support;
an alignment film; and
a second liquid crystal layer,
wherein the transparent support, the alignment film, the liquid crystal layer, the light absorption anisotropic film, and the second liquid crystal layer are provided in order,
the second liquid crystal layer is a layer which contains a liquid crystal compound aligned therein and has a thickness of 300 nm or less, and
the absorption axis of the light absorption anisotropic film and a slow axis of the second liquid crystal layer are parallel to each other.

7. The laminate according to claim 1,
wherein the light absorption anisotropic film is a film formed of a composition containing the dichroic material and a liquid crystal compound.

8. The laminate according to claim 1,
wherein the dichroic material is a compound represented by Formula (1), 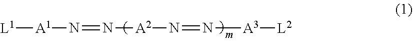
in Formula (1), A¹, A², and A³ each independently represent a divalent aromatic group which may have a substituent,
in Formula (1), L¹ and L² each independently represent a substituent, and
in Formula (1), m represents an integer of 1 to 4, and in a case where m represents an integer of 2 to 4, a plurality of A²'s may be the same as or different from each other.

9. The laminate according to claim 1,
wherein the dichroic material is a compound represented b Formula (2), 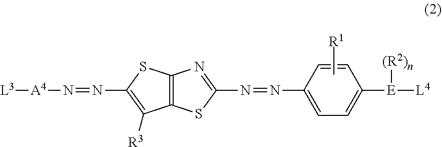
in Formula (2), A⁴ represents a divalent aromatic group which may have a substituent,
in Formula (2), L³ and L⁴ each independently represent a substituent,
in Formula (2), E represents any of a nitrogen atom, an oxygen atom, or a sulfur atom,
in Formula (2), R¹ represents any of a hydrogen atom, a halogen atom, an alkyl group which may have a substituent, or an alkoxy group which may have a substituent,
in Formula (2), R² represents a hydrogen atom or an alkyl group which may have a substituent,
in Formula (2), R³ represents a hydrogen atom or a substituent, and
in Formula (2), n represents 0 or 1, where n is 1 in a case where E represents a nitrogen atom, and n is 0 in a case where E represents an oxygen atom or a sulfur atom.

10. The laminate according to claim 9,
wherein in Formula (2), A⁴ represents a phenylene group.

11. The laminate according to claim 9,
wherein in Formula (2), at least one of L³ or L⁴ contains a crosslinkable group.

12. The laminate according to claim 9,
wherein in Formula (2), both L³ and L⁴ contain a crosslinkable group.

13. The laminate according to claim 11,
wherein the crosslinkable group is an acryloyl group or a methacryloyl group.

14. The laminate according to claim 1, further comprising:
a λ/4 plate.

15. An image display device comprising:
the laminate according to claim 1.
